(19) United States
(12) Patent Application Publication
(10) Pub. No.: US 2025/0384191 A1
(43) Pub. Date: Dec. 18, 2025

(54) DRILLING OPERATIONS FRAMEWORK

(71) Applicant: Schlumberger Technology Corporation, Sugar Land, TX (US)

(72) Inventors: Andrew Poor, Sugar Land, TX (US); Paul Bolchover, Houston, TX (US); Gang Xu, Beijing (CN); Feng Feng, Beijing (CN)

(21) Appl. No.: 18/740,550

(22) Filed: Jun. 12, 2024

(51) Int. Cl. G06F 30/28

(52) U.S. Cl. CPC G06F 30/28

(57) ABSTRACT

A method may include receiving a request to select a piece of equipment for performing a field operation at a site; responsive to the request, automatically generating scenarios for a number of candidate pieces of equipment, executing simulations to generate simulation results for the scenarios, and, based at least in part on the simulation results, computing performance indicators for the scenarios; and outputting the performance indicators according to a schema for rendering graphics to a display.

### BACKGROUND

A reservoir may be a subsurface formation that may be characterized at least in part by its porosity and fluid permeability. As an example, a reservoir may be part of a basin such as a sedimentary basin. A basin may be a depression (e.g., caused by plate tectonic activity, subsidence, etc.) in which sediments accumulate. As an example, where hydrocarbon source rocks occur in combination with appropriate depth and duration of burial, a petroleum system may develop within a basin, which may form a reservoir that includes hydrocarbon fluids (e.g., oil, gas, etc.).

In oil and gas exploration, interpretation is a process that involves analysis of data to identify and locate various subsurface structures (e.g., horizons, faults, geobodies, etc.) in a geologic environment. Various types of structures (e.g., stratigraphic formations) may be indicative of hydrocarbon traps or flow channels, as may be associated with one or more reservoirs (e.g., fluid reservoirs). In the field of resource extraction, enhancements to interpretation may allow for construction of a more accurate model of a subsurface region, which, in turn, may improve characterization of the subsurface region for purposes of resource extraction. Characterization of one or more subsurface regions in a geologic environment may guide, for example, performance of one or more operations (e.g., field operations, etc.). As an example, a plan may depend on a model of a subsurface region where the plan may specify how a drilling operation may accurately construct a borehole according to a trajectory that penetrates a reservoir, etc., where fluid may be produced via the borehole (e.g., as a completed well, etc.). As an example, one or more workflows may be performed using one or more computational frameworks, systems, etc., for one or more of analysis, acquisition, model building, control, etc., for exploration, interpretation, drilling, fracturing, production, etc.

### SUMMARY

A method may include receiving a request to select a piece of equipment for performing a field operation at a site; responsive to the request, automatically generating scenarios for a number of candidate pieces of equipment, executing simulations to generate simulation results for the scenarios, and, based at least in part on the simulation results, computing performance indicators for the scenarios; and outputting the performance indicators according to a schema for rendering graphics to a display. A system may include one or more processors; memory accessible to at least one of the one or more processors; and processor-executable instructions stored in the memory and executable to instruct the system to: receive a request to select a piece of equipment for performing a field operation at a site; responsive to the request, automatically generate scenarios for a number of candidate pieces of equipment, execute simulations to generate simulation results for the scenarios, and, based at least in part on the simulation results, compute performance indicators for the scenarios; and output the performance indicators according to a schema for rendering graphics to a display. One or more computer-readable storage media may include processor-executable instructions to instruct a computing system to: receive a request to select a piece of equipment for performing a field operation at a site; responsive to the request, automatically generate scenarios for a number of candidate pieces of equipment, execute simulations to generate simulation results for the scenarios, and, based at least in part on the simulation results, compute performance indicators for the scenarios; and output the performance indicators according to a schema for rendering graphics to a display. Various other apparatuses, systems, methods, etc., are also disclosed.

This summary is provided to introduce a selection of concepts that are further described below in the detailed description. This summary is not intended to identify key or essential features of the claimed subject matter, nor is it intended to be used as an aid in limiting the scope of the claimed subject matter.

### BRIEF DESCRIPTION OF THE DRAWINGS

The following detailed description refers to the accompanying drawings. Wherever convenient Features and advantages of the described implementations may be more readily understood by reference to the following description taken in conjunction with the accompanying drawings.

FIG. 1 shows an example of a system;

FIG. 2 shows an example of a system;

FIG. 3 shows an example of a system;

FIG. 4 shows an example of a system;

FIG. 5 shows an example of a method;

FIG. 6 shows an example plot as to drilling control and example graphics as to drilling behaviors;

FIG. 7 shows an example of a system;

FIG. 8 shows an example of a system;

FIG. 9 shows an example of a system;

FIG. 10 shows an example of a system;

FIG. 11 shows an example of a system;

FIG. 12 shows an example of a system;

FIG. 13 shows an example of a graphical user interface;

FIG. 14 shows an example of a system;

FIG. 15 shows an example of a graphical user interface;

FIG. 16 shows an example of a schema;

FIG. 17 shows an example of a graphical user interface;

FIG. 18 shows an example of a graphical user interface;

FIG. 19 shows an example of a graphical user interface;

FIG. 20 shows an example of a method and an example of a system;

FIG. 21 shows an example of a workflow; and

FIG. 22 shows an example of a system.

### DETAILED DESCRIPTION

This description is not to be taken in a limiting sense, but rather is made merely for the purpose of describing the general principles of the implementations. The scope of the described implementations should be ascertained with reference to the issued claims.

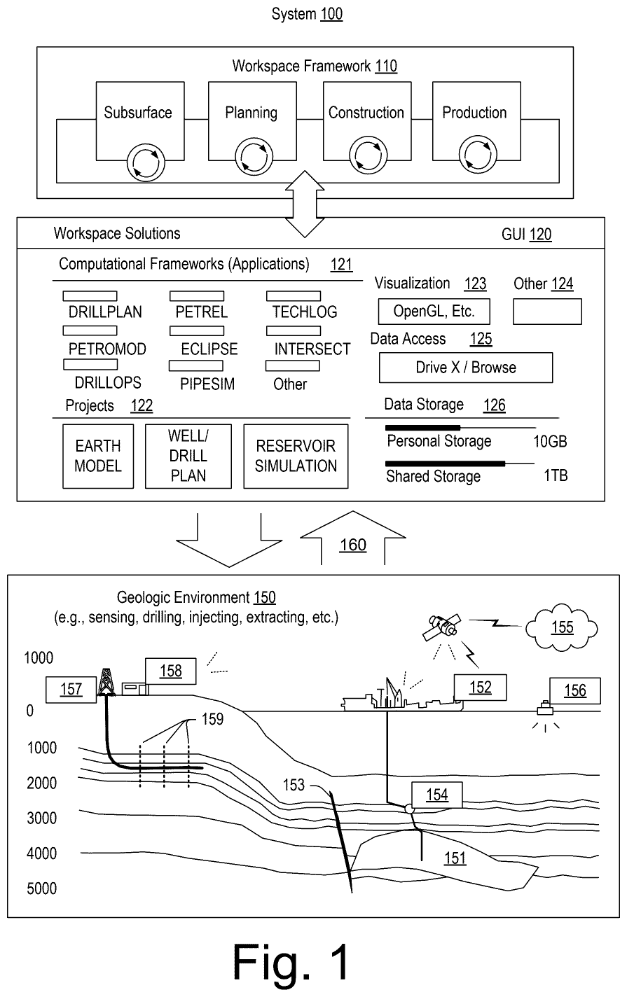

FIG. 1 shows an example of a system 100 that includes a workspace framework 110 that may provide for instantiation of, rendering of, interactions with, etc., a graphical user interface (GUI) 120. In the example of FIG. 1, the GUI 120 may include graphical controls for computational frameworks (e.g., applications, etc.) 121, projects 122, visualization features 123, one or more other features 124, data access 125, and data storage 126.

In the example of FIG. 1, the workspace framework 110 may be tailored to a particular geologic environment such as an example geologic environment 150. For example, the geologic environment 150 may include layers (e.g., stratification) that include a reservoir 151 and that may be intersected by a fault 153. As an example, the geologic environment 150 may be outfitted with a variety of sensors, detectors, actuators, etc. For example, equipment 152 may include communication circuitry to receive and to transmit information with respect to one or more networks 155. Such information may include information associated with downhole equipment 154, which may be equipment to acquire information, to assist with resource recovery, etc. Other equipment 156 may be located remote from a wellsite and include sensing, detecting, emitting or other circuitry. Such equipment may include storage and communication circuitry to store and to communicate data, instructions, etc. As an example, one or more satellites may be provided for purposes of communications, data acquisition, etc. For example, FIG. 1 shows a satellite in communication with the network 155 that may be configured for communications, noting that the satellite may additionally or alternatively include circuitry for imagery (e.g., spatial, spectral, temporal, radiometric, etc.).

FIG. 1 also shows the geologic environment 150 as optionally including equipment 157 and 158 associated with a well that includes a substantially horizontal portion that may intersect with one or more fractures 159. For example, consider a well in a shale formation that may include natural fractures, artificial fractures (e.g., hydraulic fractures) or a combination of natural and artificial fractures. As an example, a well may be drilled for a reservoir that is laterally extensive. In such an example, lateral variations in properties, stresses, etc. may exist where an assessment of such variations may assist with planning, operations, etc. to develop a laterally extensive reservoir (e.g., via fracturing, injecting, extracting, etc.). As an example, the equipment 157 and/or 158 may include components, a system, systems, etc. for fracturing, seismic sensing, analysis of seismic data, assessment of one or more fractures, etc.

In the example of FIG. 1, the GUI 120 shows some examples of computational frameworks, including the DRILLPLAN, DRILLOPS, PETREL, TECHLOG, PETROMOD, ECLIPSE, PIPESIM, and INTERSECT frameworks (SLB, Houston, Texas).

The DRILLPLAN framework provides for digital well construction planning and includes features for automation of repetitive tasks and validation workflows, enabling improved quality drilling programs (e.g., digital drilling plans, etc.) to be produced quickly with assured coherency.

The DRILLOPS framework may execute a digital drilling plan and ensures plan adherence, while delivering goal-based automation. The DRILLOPS framework may generate activity plans automatically individual operations, whether they are monitored and/or controlled on the rig or in town. Automation may utilize data analysis and learning systems to assist and optimize tasks, such as, for example, setting ROP to drilling a stand. A preset menu of automatable drilling tasks may be rendered, and, using data analysis and models, a plan may be executed in a manner to achieve a specified goal, where, for example, measurements may be utilized for calibration. The DRILLOPS framework provides flexibility to modify and replan activities dynamically, for example, based on a live appraisal of various factors (e.g., equipment, personnel, and supplies). Well construction activities (e.g., tripping, drilling, cementing, etc.) may be continually monitored and dynamically updated using feedback from operational activities. The DRILLOPS framework may provide for various levels of automation based on planning and/or re-planning (e.g., via the DRILLPLAN framework), feedback, etc.

The PETREL framework may be part of the DELFI environment for utilization in geosciences and geoengineering, for example, to analyze subsurface data from exploration to production of fluid from a reservoir. The DELFI cognitive exploration and production (E&P) environment (SLB, Houston, Texas), referred to herein as the DELFI environment or DELFI framework, is a secure, cognitive, cloud-based collaborative environment that integrates data and workflows with digital technologies, such as artificial intelligence and machine learning.

The PETREL framework provides components that allow for optimization of various exploration, development and production operations. The PETREL framework includes seismic to simulation software components that may output information for use in increasing reservoir performance, for example, by improving asset team productivity. Through use of such a framework, various professionals (e.g., geophysicists, geologists, and reservoir engineers) may develop collaborative workflows and integrate operations to streamline processes (e.g., with respect to one or more geologic environments, etc.). Such a framework may be considered an application (e.g., executable using one or more devices) and may be considered a data-driven application (e.g., where data is input for purposes of modeling, simulating, etc.).

The TECHLOG framework may handle and process field and laboratory data for a variety of geologic environments (e.g., deepwater exploration, shale, etc.). The TECHLOG framework may structure wellbore data for analyses, planning, etc.

The PETROMOD framework provides petroleum systems modeling capabilities that may combine one or more of seismic, well, and geological information to model the evolution of a sedimentary basin. The PETROMOD framework may predict if, and how, a reservoir has been charged with hydrocarbons, including the source and timing of hydrocarbon generation, migration routes, quantities, and hydrocarbon type in the subsurface or at surface conditions.

The ECLIPSE framework provides a reservoir simulator (e.g., as a computational framework) with numerical solutions for fast and accurate prediction of dynamic behavior for various types of reservoirs and development schemes.

The INTERSECT framework provides a high-resolution reservoir simulator for simulation of detailed geological features and quantification of uncertainties, for example, by creating accurate production scenarios and, with the integration of precise models of the surface facilities and field operations, the INTERSECT framework may produce reliable results, which may be continuously updated by real-time data exchanges (e.g., from one or more types of data acquisition equipment in the field that may acquire data during one or more types of field operations, etc.). The INTERSECT framework may provide completion configurations for complex wells where such configurations may be built in the field, may provide detailed enhanced-oil-recovery (EOR) formulations where such formulations may be implemented in the field, may analyze application of steam injection and other thermal EOR techniques for implementation in the field, advanced production controls in terms of reservoir coupling and flexible field management, and flexibility to script customized solutions for improved modeling and field management control. The INTERSECT framework, as with the other example frameworks, may be utilized as part of the DELFI environment, for example, for rapid simulation of multiple concurrent cases. For example, a workflow may utilize one or more of the DELFI environment on demand reservoir simulation features.

The aforementioned DELFI environment provides various features for workflows as to subsurface analysis, planning, construction and production, for example, as illustrated in the workspace framework 110. As shown in FIG. 1, outputs from the workspace framework 110 may be utilized for directing, controlling, etc., one or more processes in the geologic environment 150 and, feedback 160, may be received via one or more interfaces in one or more forms (e.g., acquired data as to operational conditions, equipment conditions, environment conditions, etc.).

As an example, a workflow may progress to a geology and geophysics (“G&G”) service provider, which may generate a well trajectory, which may involve execution of one or more G&G frameworks (e.g., consider the PETREL framework, etc.).

In the example of FIG. 1, the visualization features 123 may be implemented via the workspace framework 110, for example, to perform tasks as associated with one or more of subsurface regions, planning operations, constructing wells and/or surface fluid networks, and producing from a reservoir.

As an example, a visualization process may implement one or more of various features that may be suitable for one or more web applications. For example, a template may involve use of the JAVASCRIPT object notation format (JSON) and/or one or more other languages/formats. As an example, a framework may include one or more converters. For example, consider a JSON to PYTHON converter and/or a PYTHON to JSON converter. Such an approach may provide for compatibility of devices, frameworks, etc., with respect to one or more sets of instructions.

As an example, visualization features may provide for visualization of various earth models, properties, etc., in one or more dimensions. As an example, visualization features may provide for rendering of information in multiple dimensions, which may optionally include multiple resolution rendering. In such an example, information being rendered may be associated with one or more frameworks and/or one or more data stores. As an example, visualization features may include one or more control features for control of equipment, which may include, for example, field equipment that may perform one or more field operations. As an example, a workflow may utilize one or more frameworks to generate information that may be utilized to control one or more types of field equipment (e.g., drilling equipment, wireline equipment, fracturing equipment, etc.).

As to a reservoir model that may be suitable for utilization by a simulator, consider acquisition of seismic data as acquired via reflection seismology, which finds use in geophysics, for example, to estimate properties of subsurface formations. As an example, reflection seismology may provide seismic data representing waves of elastic energy (e.g., as transmitted by P-waves and S-waves, in a frequency range of approximately 1 Hz to approximately 100 Hz). Seismic data may be processed and interpreted, for example, to understand better composition, fluid content, extent and geometry of subsurface rocks. Such interpretation results may be utilized to plan, simulate, perform, etc., one or more operations for production of fluid from a reservoir (e.g., reservoir rock, etc.).

As an example, a model may be a simulated version of a geologic environment. As an example, a simulator may include features for simulating physical phenomena in a geologic environment based at least in part on a model or models. A simulator, such as a reservoir simulator, may simulate fluid flow in a geologic environment based at least in part on a model that may be generated via a framework that receives seismic data. A simulator may be a computerized system (e.g., a computing system) that may execute instructions using one or more processors to solve a system of equations that describe physical phenomena subject to various constraints. In such an example, the system of equations may be spatially defined (e.g., numerically discretized) according to a spatial model that that includes layers of rock, geobodies, etc., that have corresponding positions that may be based on interpretation of seismic and/or other data. A spatial model may be a cell-based model where cells are defined by a grid (e.g., a mesh). A cell in a cell-based model may represent a physical area or volume in a geologic environment where the cell may be assigned physical properties (e.g., permeability, fluid properties, etc.) that may be germane to one or more physical phenomena (e.g., fluid volume, fluid flow, pressure, etc.). A reservoir simulation model may be a spatial model that may be cell-based.

While several simulators are illustrated in the example of FIG. 1, one or more other simulators may be utilized, additionally or alternatively. For example, consider the VISAGE geomechanics simulator (SLB, Houston Texas) or the PIPESIM network simulator (SLB, Houston Texas), etc.

As an example, a workflow may utilize one or more types of data for one or more processes (e.g., stratigraphic modeling, basin modeling, completion designs, drilling, production, injection, etc.). As an example, one or more tools may provide data that may be used in a workflow or workflows that may implement one or more frameworks (e.g., PETREL, TECHLOG, PETROMOD, ECLIPSE, etc.).

In the example of FIG. 1, drilling may be performed in the geologic environment 150, for example, to access the reservoir 151, which may be accessed from land or offshore. In FIG. 1, the downhole equipment 154 may be, for example, part of a bottom hole assembly (BHA). The BHA may be used to drill a well. The downhole equipment 154 may communicate information to equipment at the surface, and may receive instructions and information from the equipment at the surface. During a well construction process, a variety of operations (such as cementing, wireline evaluation, testing, etc.) may be conducted. In such embodiments, data collected by tools and sensors and used for reasons such as reservoir characterization may be collected and transmitted.

A well may include a substantially horizontal portion (e.g., lateral portion) that may intersect with one or more fractures. For example, a well in a shale formation may pass through natural fractures, artificial fractures (e.g., hydraulic fractures), or a combination thereof. Such a well may be constructed using directional drilling techniques as described herein. However, these same techniques may be used in connection with other types of directional wells (such as slant wells, S-shaped wells, deep inclined wells, and others) and are not limited to horizontal wells.

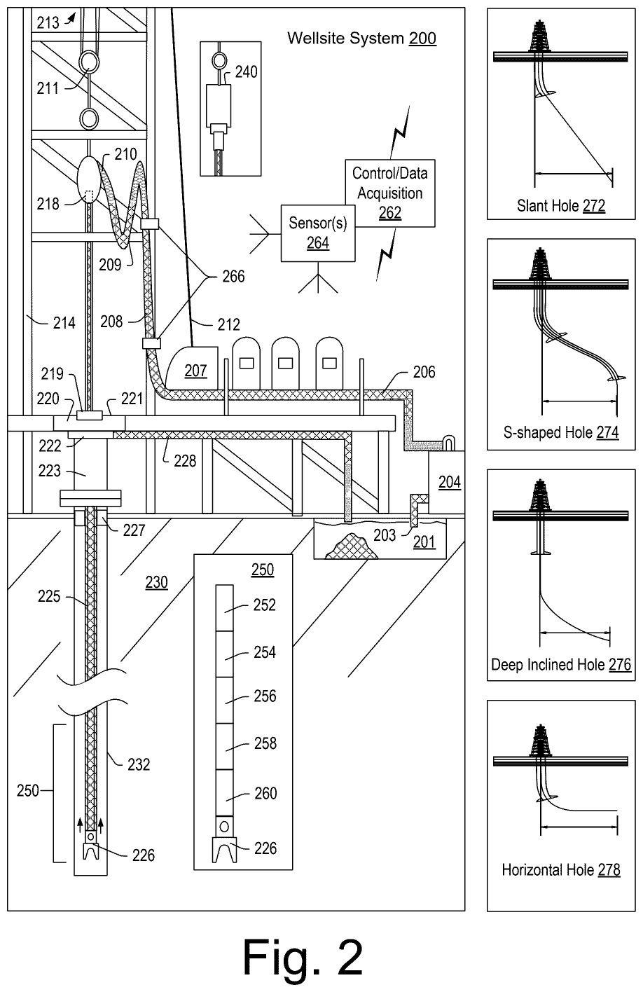

FIG. 2 shows an example of a wellsite system 200 (e.g., at a wellsite that may be onshore or offshore). As shown, the wellsite system 200 may include a mud tank 201 for holding mud and other material (e.g., where mud may be a drilling fluid), a suction line 203 that serves as an inlet to a mud pump 204 for pumping mud from the mud tank 201 such that mud flows to a vibrating hose 206, a drawworks 207 for winching drill line or drill lines 212, a standpipe 208 that receives mud from the vibrating hose 206, a kelly hose 209 that receives mud from the standpipe 208, a gooseneck or goosenecks 210, a traveling block 211, a crown block 213 for carrying the traveling block 211 via the drill line or drill lines 212, a derrick 214, a kelly 218 or a top drive 240, a kelly drive bushing 219, a rotary table 220, a drill floor 221, a bell nipple 222, one or more blowout preventors (BOPs) 223, a drillstring 225, a drill bit 226, a casing head 227 and a flow pipe 228 that carries mud and other material to, for example, the mud tank 201.

In the example system of FIG. 2, a borehole 232 is formed in subsurface formations 230 by rotary drilling; noting that various example embodiments may also use one or more directional drilling techniques, equipment, etc.

As shown in the example of FIG. 2, the drillstring 225 is suspended within the borehole 232 and has a drillstring assembly 250 that includes the drill bit 226 at its lower end. As an example, the drillstring assembly 250 may be a bottom hole assembly (BHA).

The wellsite system 200 may provide for operation of the drillstring 225 and other operations. As shown, the wellsite system 200 includes the traveling block 211 and the derrick 214 positioned over the borehole 232. As mentioned, the wellsite system 200 may include the rotary table 220 where the drillstring 225 pass through an opening in the rotary table 220.

As shown in the example of FIG. 2, the wellsite system 200 may include the kelly 218 and associated components, etc., or a top drive 240 and associated components. As to a kelly example, the kelly 218 may be a square or hexagonal metal/alloy bar with a hole drilled therein that serves as a mud flow path. The kelly 218 may be used to transmit rotary motion from the rotary table 220 via the kelly drive bushing 219 to the drillstring 225, while allowing the drillstring 225 to be lowered or raised during rotation. The kelly 218 may pass through the kelly drive bushing 219, which may be driven by the rotary table 220. As an example, the rotary table 220 may include a master bushing that operatively couples to the kelly drive bushing 219 such that rotation of the rotary table 220 may turn the kelly drive bushing 219 and hence the kelly 218. The kelly drive bushing 219 may include an inside profile matching an outside profile (e.g., square, hexagonal, etc.) of the kelly 218; however, with slightly larger dimensions so that the kelly 218 may freely move up and down inside the kelly drive bushing 219.

As to a top drive example, the top drive 240 may provide functions performed by a kelly and a rotary table. The top drive 240 may turn the drillstring 225. As an example, the top drive 240 may include one or more motors (e.g., electric and/or hydraulic) connected with appropriate gearing to a short section of pipe called a quill, that in turn may be screwed into a saver sub or the drillstring 225 itself. The top drive 240 may be suspended from the traveling block 211, so the rotary mechanism is free to travel up and down the derrick 214. As an example, a top drive 240 may allow for drilling to be performed with more joint stands than a kelly/rotary table approach.

In the example of FIG. 2, the mud tank 201 may hold mud, which may be one or more types of drilling fluids. As an example, a wellbore may be drilled to produce fluid, inject fluid or both (e.g., hydrocarbons, minerals, water, etc.).

In the example of FIG. 2, the drillstring 225 (e.g., including one or more downhole tools) may be composed of a series of pipes threadably connected together to form a long tube with the drill bit 226 at the lower end thereof. As the drillstring 225 is advanced into a wellbore for drilling, at some point in time prior to or coincident with drilling, the mud may be pumped by the pump 204 from the mud tank 201 (e.g., or other source) via the lines 206, 208 and 209 to a port of the kelly 218 or, for example, to a port of the top drive 240. The mud may then flow via a passage (e.g., or passages) in the drillstring 225 and out of ports located on the drill bit 226 (see, e.g., a directional arrow). As the mud exits the drillstring 225 via ports in the drill bit 226, it may then circulate upwardly through an annular region between an outer surface(s) of the drillstring 225 and surrounding wall(s) (e.g., open borehole, casing, etc.), as indicated by directional arrows. In such a manner, the mud lubricates the drill bit 226 and carries heat energy (e.g., frictional or other energy) and formation cuttings to the surface where the mud (e.g., and cuttings) may be returned to the mud tank 201, for example, for recirculation (e.g., with processing to remove cuttings, etc.).

The mud pumped by the pump 204 into the drillstring 225 may, after exiting the drillstring 225, form a mudcake that lines the wellbore which, among other functions, may reduce friction between the drillstring 225 and surrounding wall(s) (e.g., borehole, casing, etc.). A reduction in friction may facilitate advancing or retracting the drillstring 225. During a drilling operation, the entire drillstring 225 may be pulled from a wellbore and optionally replaced, for example, with a new or sharpened drill bit, a smaller diameter drillstring, etc. As mentioned, the act of pulling a drillstring out of a hole or replacing it in a hole is referred to as tripping. A trip may be referred to as an upward trip or an outward trip or as a downward trip or an inward trip depending on trip direction.

As an example, consider a downward trip where upon arrival of the drill bit 226 of the drillstring 225 at a bottom of a wellbore, pumping of the mud commences to lubricate the drill bit 226 for purposes of drilling to enlarge the wellbore. As mentioned, the mud may be pumped by the pump 204 into a passage of the drillstring 225 and, upon filling of the passage, the mud may be used as a transmission medium to transmit energy, for example, energy that may encode information as in mud-pulse telemetry.

As an example, mud-pulse telemetry equipment may include a downhole device configured to effect changes in pressure in the mud to create an acoustic wave or waves upon which information may modulated. In such an example, information from downhole equipment (e.g., one or more modules of the drillstring 225) may be transmitted uphole to an uphole device, which may relay such information to other equipment for processing, control, etc.

As an example, telemetry equipment may operate via transmission of energy via the drillstring 225 itself. For example, consider a signal generator that imparts coded energy signals to the drillstring 225 and repeaters that may receive such energy and repeat it to further transmit the coded energy signals (e.g., information, etc.).

As an example, the drillstring 225 may be fitted with telemetry equipment 252 that includes a rotatable drive shaft, a turbine impeller mechanically coupled to the drive shaft such that the mud may cause the turbine impeller to rotate, a modulator rotor mechanically coupled to the drive shaft such that rotation of the turbine impeller causes said modulator rotor to rotate, a modulator stator mounted adjacent to or proximate to the modulator rotor such that rotation of the modulator rotor relative to the modulator stator creates pressure pulses in the mud, and a controllable brake for selectively braking rotation of the modulator rotor to modulate pressure pulses. In such an example, an alternator may be coupled to the aforementioned drive shaft where the alternator includes at least one stator winding electrically coupled to a control circuit to selectively short the at least one stator winding to electromagnetically brake the alternator and thereby selectively brake rotation of the modulator rotor to modulate the pressure pulses in the mud.

In the example of FIG. 2, an uphole control and/or data acquisition system 262 may include circuitry to sense pressure pulses generated by telemetry equipment 252 and, for example, communicate sensed pressure pulses or information derived therefrom for process, control, etc.

The assembly 250 of the illustrated example includes a logging-while-drilling (LWD) module 254, a measurement-while-drilling (MWD) module 256, an optional module 258, a rotary-steerable system (RSS) and/or motor 260, and the drill bit 226. Such components or modules may be referred to as tools where a drillstring may include a plurality of tools.

As to an RSS, it involves technology utilized for directional drilling. Directional drilling involves drilling into the Earth to form a deviated bore such that the trajectory of the bore is not vertical; rather, the trajectory deviates from vertical along one or more portions of the bore. As an example, consider a target that is located at a lateral distance from a surface location where a rig may be stationed. In such an example, drilling may commence with a vertical portion and then deviate from vertical such that the bore is aimed at the target and, eventually, reaches the target. Directional drilling may be implemented where a target may be inaccessible from a vertical location at the surface of the Earth, where material exists in the Earth that may impede drilling or otherwise be detrimental (e.g., consider a salt dome, etc.), where a formation is laterally extensive (e.g., consider a relatively thin yet laterally extensive reservoir), where multiple bores are to be drilled from a single surface bore, where a relief well is desired, etc.

One approach to directional drilling involves a mud motor; however, a mud motor may present some challenges depending on factors such as rate of penetration (ROP), transferring weight to a bit (e.g., weight on bit, WOB) due to friction, etc. A mud motor may be a positive displacement motor (PDM) that operates to drive a bit (e.g., during directional drilling, etc.). A PDM operates as drilling fluid is pumped through it where the PDM converts hydraulic power of the drilling fluid into mechanical power to cause the bit to rotate.

As an example, a mud motor (e.g., PDM) may be operated in different modes, which may include a rotating mode and a sliding mode. A sliding mode involves drilling with a mud motor rotating the bit downhole without rotating the drillstring from the surface; noting that the drillstring may be oscillated from the surface clockwise and counter-clockwise to reduce friction, etc. Such an operation may be conducted when a BHA has been fitted with a bent sub or a bent housing mud motor, or both, for directional drilling. Sliding may be used in building and controlling or adjusting hole angle. In directional drilling, pointing of a bit may be accomplished through a bent sub, which may have a relatively small angle offset from the axis of a drillstring, and a measurement device to determine the direction of offset. Without turning the drillstring as in rotary drilling (e.g., a rotating mode), the bit may be rotated with mud flow through the mud motor to drill in the direction it is pointed. With steerable motors, when a desired wellbore direction is attained, the entire drillstring may be rotated to drill straight rather than at an angle. By controlling the amount of hole drilled in the sliding mode versus the rotating mode, a wellbore trajectory may be controlled rather precisely.

As an example, a PDM may operate in a combined rotating mode where surface equipment is utilized to rotate a bit of a drillstring (e.g., a rotary table, a top drive, etc.) by rotating the entire drillstring and where drilling fluid is utilized to rotate the bit of the drillstring. In such an example, a surface RPM (SRPM) may be determined by use of the surface equipment and a downhole RPM of the mud motor may be determined using various factors related to flow of drilling fluid, mud motor type, etc. As an example, in the combined rotating mode, bit RPM may be determined or estimated as a sum of the SRPM and the mud motor RPM, assuming the SRPM and the mud motor RPM are in the same direction.

As an example, a PDM mud motor may operate in a so-called sliding mode, when the drillstring is not rotated from the surface. In such an example, a bit RPM may be determined or estimated based on the RPM of the mud motor.

An RSS may drill directionally where there is continuous rotation from surface equipment, which may alleviate the sliding of a steerable motor (e.g., a PDM). An RSS may be deployed when drilling directionally (e.g., deviated, horizontal, or extended-reach wells). An RSS may aim to minimize interaction with a borehole wall, which may help to preserve borehole quality. An RSS may aim to exert a relatively consistent side force akin to stabilizers that rotate with the drillstring or orient the bit in the desired direction while continuously rotating at the same number of rotations per minute as the drillstring.

The LWD module 254 may be housed in a suitable type of drill collar and may contain one or a plurality of selected types of logging tools. It will also be understood that more than one LWD and/or MWD module may be employed. Where the position of an LWD module is mentioned, as an example, it may refer to a module at the position of the LWD module 254, the MWD module 256, etc. An LWD module may include capabilities for measuring, processing, and storing information, as well as for communicating with the surface equipment. In the illustrated example, the LWD module 254 may include a seismic measuring device.

The MWD module 256 may be housed in a suitable type of drill collar and may contain one or more devices for measuring characteristics of the drillstring 225 and the drill bit 226. As an example, the MWD module 256 may include equipment for generating electrical power, for example, to power various components of the drillstring 225. As an example, the MWD module 256 may include the telemetry equipment 252, for example, where the turbine impeller may generate power by flow of the mud; it being understood that other power and/or battery systems may be employed for purposes of powering various components. As an example, the MWD module 256 may include one or more of the following types of measuring devices: a weight-on-bit measuring device, a torque measuring device, a vibration measuring device, a shock measuring device, a stick slip measuring device, a direction measuring device, and an inclination measuring device.

FIG. 2 also shows some examples of types of holes that may be drilled. For example, consider a slant hole 272, an S-shaped hole 274, a deep inclined hole 276 and a horizontal hole 278.

As an example, a drilling operation may include directional drilling where, for example, at least a portion of a well includes a curved axis. For example, consider a radius that defines curvature where an inclination with regard to the vertical may vary until reaching an angle between about 30 degrees and about 60 degrees or, for example, an angle to about 90 degrees or possibly greater than about 90 degrees.

As an example, a directional well may include several shapes where each of the shapes may aim to meet particular operational demands. As an example, a drilling process may be performed on the basis of information as and when it is relayed to a drilling engineer. As an example, inclination and/or direction may be modified based on information received during a drilling process.

As an example, deviation of a bore may be accomplished in part by use of a downhole motor and/or a turbine. As to a motor, for example, a drillstring may include a positive displacement motor (PDM).

As an example, a system may be a steerable system and include equipment to perform method such as geosteering. As mentioned, a steerable system may be or include an RSS. As an example, a steerable system may include a PDM or of a turbine on a lower part of a drillstring which, just above a drill bit, a bent sub may be mounted. As an example, above a PDM, MWD equipment that provides real time or near real time data of interest (e.g., inclination, direction, pressure, temperature, real weight on the drill bit, torque stress, etc.) and/or LWD equipment may be installed. As to the latter, LWD equipment may make it possible to send to the surface various types of data of interest, including for example, geological data (e.g., gamma ray log, resistivity, density and sonic logs, etc.).

As an example, geosteering may be employed (e.g., control of directional drilling using geological data). The coupling of sensors providing information on the course of a well trajectory, in real time or near real time, with, for example, one or more logs characterizing the formations from a geological viewpoint, may allow for implementing a geosteering method. Such a method may include navigating a subsurface environment, for example, to follow a desired route to reach a desired target or targets.

As an example, a drillstring may include an azimuthal density neutron (ADN) tool for measuring density and porosity; a MWD tool for measuring inclination, azimuth and shocks; a compensated dual resistivity (CDR) tool for measuring resistivity and gamma ray related phenomena; one or more variable gauge stabilizers; one or more bend joints; and a geosteering tool, which may include a motor and optionally equipment for measuring and/or responding to one or more of inclination, resistivity and gamma ray related phenomena.

As an example, geosteering may include intentional directional control of a wellbore based on results of downhole geological logging measurements in a manner that aims to keep a directional wellbore within a desired region, zone (e.g., a pay zone), etc. As an example, geosteering may include directing a wellbore to keep the wellbore in a particular section of a reservoir, for example, to minimize gas and/or water breakthrough and, for example, to maximize economic production from a well that includes the wellbore.

Referring again to FIG. 2, the wellsite system 200 may include one or more sensors 264 that are operatively coupled to the control and/or data acquisition system 262. As an example, a sensor or sensors may be at surface locations. As an example, a sensor or sensors may be at downhole locations. As an example, a sensor or sensors may be at one or more remote locations that are not within a distance of the order of about one hundred meters from the wellsite system 200. As an example, a sensor or sensor may be at an offset wellsite where the wellsite system 200 and the offset wellsite are in a common field (e.g., oil and/or gas field).

As an example, one or more of the sensors 264 may be provided for tracking pipe, tracking movement of at least a portion of a drillstring, etc.

As an example, the system 200 may include one or more sensors 266 that may sense and/or transmit signals to a fluid conduit such as a drilling fluid conduit (e.g., a drilling mud conduit). For example, in the system 200, the one or more sensors 266 may be operatively coupled to portions of the standpipe 208 through which mud flows. As an example, a downhole tool may generate pulses that may travel through the mud and be sensed by one or more of the one or more sensors 266. In such an example, the downhole tool may include associated circuitry such as, for example, encoding circuitry that may encode signals, for example, to reduce demands as to transmission. As an example, circuitry at the surface may include decoding circuitry to decode encoded information transmitted at least in part via mud-pulse telemetry. As an example, circuitry at the surface may include encoder circuitry and/or decoder circuitry and circuitry downhole may include encoder circuitry and/or decoder circuitry. As an example, the system 200 may include a transmitter that may generate signals that may be transmitted downhole via mud (e.g., drilling fluid) as a transmission medium.

As an example, one or more portions of a drillstring may become stuck. The term stuck may refer to one or more of varying degrees of inability to move or remove a drillstring from a bore. As an example, in a stuck condition, it might be possible to rotate pipe or lower it back into a bore or, for example, in a stuck condition, there may be an inability to move the drillstring axially in the bore, though some amount of rotation may be possible. As an example, in a stuck condition, there may be an inability to move at least a portion of the drillstring axially and rotationally.

As to the term “stuck pipe”, this may refer to a portion of a drillstring that cannot be rotated or moved axially. As an example, a condition referred to as “differential sticking” may be a condition whereby the drillstring cannot be moved (e.g., rotated or reciprocated) along the axis of the bore. Differential sticking may occur when high-contact forces caused by low reservoir pressures, high wellbore pressures, or both, are exerted over a sufficiently large area of the drillstring. Differential sticking may have time and financial cost.

As an example, a sticking force may be a product of the differential pressure between the wellbore and the reservoir and the area that the differential pressure is acting upon. This means that a relatively low differential pressure (delta p) applied over a large working area may be just as effective in sticking pipe as may a high differential pressure applied over a small area.

As an example, a condition referred to as “mechanical sticking” may be a condition where limiting or prevention of motion of the drillstring by a mechanism other than differential pressure sticking occurs. Mechanical sticking may be caused, for example, by one or more of junk in the hole, wellbore geometry anomalies, cement, keyseats or a buildup of cuttings in the annulus.

As explained, a wellsite system may include various types of equipment for handling fluid such as, for example, drilling fluid (e.g., mud). As explained, drilling fluid may provide one or more functions (e.g., lubrication, transport of cutting, etc.).

Drilling fluid may be composed of a number of liquid and/or gaseous fluids and mixtures of fluids and solids (e.g., as solid suspensions, mixtures and emulsions of liquids, gases and solids) as may be used in various operations to drill boreholes into the earth. Classifications of drilling fluids may utilize one or more types of classification schemes. For example, consider water-based mud (WBM), oil-based mud (OBM), nonaqueous-based mud (NQBM), gaseous-based mud (e.g., pneumatic, etc.) (GBM), etc.

As explained, a drillstring may include a mud motor that is rotationally driven by flow of drilling fluid. In such a mode of drilling, the characteristics of drilling fluid may impact mud motor performance. For example, density (e.g., mud weight) may impact how much energy the mud motor may deliver to a drill bit for a given drilling fluid flow rate.

As to a stuck pipe or risk of sticking event, as explained, one or more actions may be taken. For example, consider addition of acid as a remedial action to address the stuck pipe event or to reduce the risk of a sticking event. In such an example, a number of barrels of acid may be added to drilling fluid that is circulated downhole to an annular region between a drilling string and a bore wall in an effort to “dissolve” material that is causing sticking or a risk of sticking. While addition of acid is mentioned, it may be an action within a tiered series of actions that may be taken, where, for example, each action may have associated benefits and detriments. As to detriments, these may include non-productive time (NPT), cost, further remedial actions (e.g., impact of acid on one or more additives in drilling fluid), etc. Hence, where an event occurs or a risk of an event is heightened, in an effort to maintain adherence to a plan, one or more actions may be implemented in a strategic manner to resolve the event or otherwise reduce the risk.

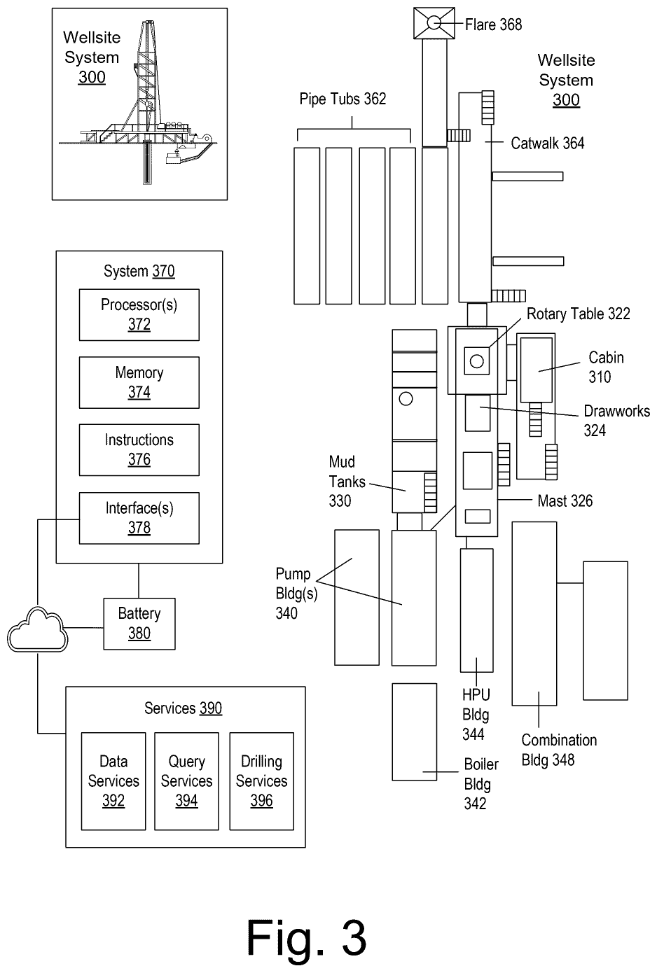

FIG. 3 shows an example of a wellsite system 300, specifically, FIG. 3 shows the wellsite system 300 in an approximate side view and an approximate plan view along with a block diagram of a system 370.

In the example of FIG. 3, the wellsite system 300 may include a cabin 310, a rotary table 322, drawworks 324, a mast 326 (e.g., optionally carrying a top drive, etc.), mud tanks 330 (e.g., with one or more pumps, one or more shakers, etc.), one or more pump buildings 340, a boiler building 342, an HPU building 344 (e.g., with a rig fuel tank, etc.), a combination building 348 (e.g., with one or more generators, etc.), pipe tubs 362, a catwalk 364, a flare 368, etc. Such equipment may include one or more associated functions and/or one or more associated operational risks, which may be risks as to time, resources, and/or humans.

As shown in the example of FIG. 3, the wellsite system 300 may include a system 370 that includes one or more processors 372, memory 374 operatively coupled to at least one of the one or more processors 372, instructions 376 that may be, for example, stored in the memory 374, and one or more interfaces 378. As an example, the system 370 may include one or more processor-readable media that include processor-executable instructions executable by at least one of the one or more processors 372 to cause the system 370 to control one or more aspects of the wellsite system 300. In such an example, the memory 374 may be or include the one or more processor-readable media where the processor-executable instructions may be or include instructions. As an example, a processor-readable medium may be a computer-readable storage medium that is not a signal and that is not a carrier wave.

FIG. 3 also shows a battery 380 that may be operatively coupled to the system 370, for example, to power the system 370. As an example, the battery 380 may be a back-up battery that operates when another power supply is unavailable for powering the system 370. As an example, the battery 380 may be operatively coupled to a network, which may be a cloud network. As an example, the battery 380 may include smart battery circuitry and may be operatively coupled to one or more pieces of equipment via a SMBus or other type of bus.

In the example of FIG. 3, services 390 are shown as being available, for example, via a cloud platform. Such services may include data services 392, query services 394 and drilling services 396. As an example, the services 390 may be part of a system such as the system 100 of FIG. 1 (e.g., consider planning services and/or operational services). As an example, the services 390 may include one or more services for directional drilling (e.g., consider a computational framework that may provide for one or more services that utilize real-time data to estimate one or more parameters, etc.).

As an example, the system 370 may be utilized to generate one or more rate of penetration drilling parameter values, which may, for example, be utilized to control one or more drilling operations.

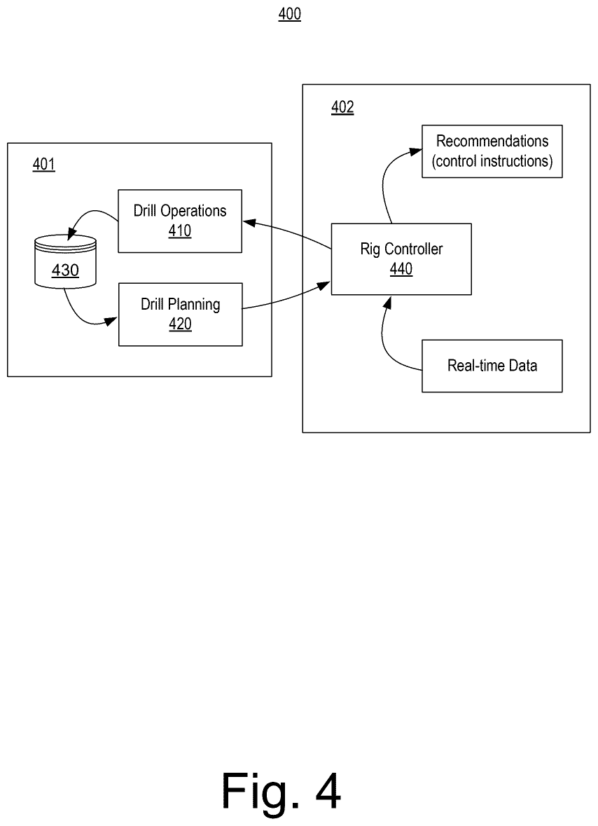

FIG. 4 shows an example of a system 400 that includes offsite equipment 401 (e.g., remote) and onsite equipment 402 (e.g., local). As shown, the offsite equipment 401 may include a drill operations framework 410, a drill planning framework 420 and a database 430 and the onsite equipment 402 may include a controller 440 that may receive real-time data and output recommendations such as control instructions to control onsite equipment. In such an example, the drill operations framework 410 may provide for steering sheets, execution parameters, etc., and the drill planning framework 420 may provide for evaluation of steering responses and statistics. As shown, the controller 440 may output information to the drill operations framework 410 and receive information from the drill planning framework 420. The system 400 may include plan generation features for real-time plan generation during drilling operations execution phase and/or plan generation during a planning phase. The system 400 may be utilized for one or more types of drilling (e.g., rotary, mud motor, RSS, ABSS, etc.). The system 400 may operate loops, which may include at least one real-time loop that provides for control of equipment to perform drilling operations.

A system such as the system 400 may utilize various functions and constraints for generation of plans, which may provide for single or multiple target aiming. As explained, a plan may be generated that aims to provide for drilling operations for a multiwell structure. As explained, a plan may be a digital plan that may be utilized to instruct one or more controllers such as, for example, an autodriller controller, which may control one or more pieces of equipment (e.g., a drawworks, a top drive, one or more drilling fluid pumps, etc.). As an example, an autodriller may control energy delivered via one or more pieces of equipment to a drill bit where the drill bit crushes and/or cuts rock to extend a borehole. As an example, an autodriller may be controlled in an effort that aims to minimize or otherwise reduce mechanical specific energy (MSE) and to maximize or otherwise increase rate of penetration (ROP).

As explained with respect to the system 100 of FIG. 1, various computational frameworks may be utilized to perform one or more workflows, which may include planning workflows, workflows involving control of field operations, workflows in real-time or near real-time, assessment workflows (e.g., for issues, successes, etc.), etc. As explained, one or more visualization features may be provided and utilized, for example, to implement visualization processes that may be suitable for one or more web applications. As mentioned, JSON and/or one or more other languages and/or formats may be utilized.

As an example, a framework may provide for generation of performance indicators for equipment. In such an example, the framework may include various automated procedures that may, for example, respond to one or more triggers to generate performance indicators for equipment. As an example, one or more performance indicators may be utilized by one or more other frameworks. For example, consider a workflow where automated generation of one or more performance indicators may cause one or more actions by one or more other frameworks, which may provide for tasks such as, for example, planning, optimization, control of field operations, etc.

As an example, equipment may be drillstring equipment such as, for example, one or more of a drill bit, a BHA, a module, a sensor, a collar, etc. In various instances, equipment may be specified within one or more databases. For example, consider a supplier catalog that may include equipment specified according to one or more identifiers, which may include, for example, a bill of material (BOM).

As an example, a supplier and/or manufacturer of equipment may have access to an extensive library of field data from around the world that may help to identify which types of equipment, etc., may be suitable for one or more types of field operations. For example, consider drill bits (e.g., bits) where design of a drill bit (e.g., a bit) may involve use of particular cutting elements and arrangements thereof. In various instances, equipment may be characterized by one or more performance indicators that may be related to equipment itself and/or interactions of equipment in an environment, for example, under various conditions. As to bits, field success may provide for driving ongoing design improvements, which may lead to superior, solution-specific bits that, for example, fail rock quicker and more effectively, withstand impact and wear longer, help to optimize ROP, etc.

As to a bit design process, it may consider rock with type of formation and lithology a bit may encounter. In various instances, a bit design process may work backwards from a rock-cutter interface where analysis continues upward along a drillstring, a drive system, one or more individual BHA components, and total system on bit behavior in a dynamic drilling environment. As an example, a process may take into account operating parameters and interactions between individual elements of a drilling assembly.

As an example, a framework may provide for implementation of a bit selection workflow. In such an example, one or more simulators (e.g., simulation frameworks, simulation engines, etc.) may be employed to generate simulation results that may aid in computation of one or more performance indicators (PIs). As an example, a framework may provide for generation of one or more graphical user interfaces (GUIs) that may provide for interactions, which may be between frameworks, workflows, etc. As an example, a GUI may provide for visualization of various PIs, which may provide for improved bit selection and/or other equipment selection. As an example, one or more PIs may be utilized by a scenario service, which may provide for generation of one or more scenarios, which may be hypothetical and/or data-based.

As an example, a simulator may be or include a drilling simulator. For example, consider one or more of the IDEAS family of simulators (IDEAS: Integrated Dynamic Engineering Analysis System, SLB, Houston, Texas). As an example, a drilling simulator may be utilized to predict downhole behavior to deal with various drilling challenges. In a workflow that involves a human-in-the-loop (HITL), as an example, a scenario service may be requested by a user (e.g., an HITL) to prepare candidate bits and then to identify the best bit based on a comprehensive report. Such a workflow may be subject to bias, latencies, lack of information, etc. To improve bit selection, a framework may provide for some level of automation where, for example, PIs may be computed using simulation results and/or other information. As an example, PIs may include one or more indicators for steerability, stability, performance, and durability. For example, consider a hierarchy of PIs where, at one level of the hierarchy, PIs may include dogleg severity (DLS), ROP, reciprocal of shock and/or vibration (1/vibration), and footage. As an example, a GUI may be rendered with an ability to generate various views. For example, consider a view focused on steerability and another view that may exclude steerability. As an example, for a particular PI, there may be one or more sub-PIs. As an example, a GUI may provide for rendering and/or interacting with graphics, fields, etc., for PIs such that graphics for one or more sub-PIs may be generated and visualized.

As an example, a framework may provide for comparing a scenario report to one or more computed PIs, which may help to facilitate decision-making by one or more individuals, one or more machines, etc. As an example, a PI-based approach may help to facility arriving at a best bit (e.g., or other piece of equipment) via a workflow that may operate smoothly and efficiently with some level of automation. Such an approach may help to expedite decision-making as to field operations, particularly when compared to manual investigation of a comprehensive scenario report.

As an example, a framework may provide for generation of PIs based at least in part on simulation results (e.g., drilling simulation results, etc.), which may provide for equipment selection where equipment may be selected from a relatively large number of candidates. For example, consider a framework that may provide for selection of a bit from ten or more candidate bits (e.g., consider dozens of candidates). In such an example, the framework may provide for automation of one or more processes, which may help to assure that the number and/or type of candidates are appropriately considered. As an example, an individual may interact with a framework for accelerating equipment selection for one or more pieces of equipment that may include drillstring equipment. In such an example, one or more databases may be accessed, augmented, etc. For example, consider an automated process that may provide for integration of newly designed bits to help assure that a database is representative of the latest equipment available, which may reflect learnings based on field operations in one or more fields under one or more conditions with, for example, one or more field operation related goals.

As explained, a framework may operate using a concept of performance indicators (PIs) that may provide for characterizing how equipment may operate in one or more environments under various conditions. As an example, a framework may provide for abstracting a set of computed PIs at a high level in a concise manner. As an example, a framework may provide for automated equipment selection using computed PIs, which may be performed in a manner, for example, that does not demand a manual process such as manually reviewing details of comprehensive simulation results.

As mentioned, a framework may include and/or be operatively coupled to one or more simulators (e.g., simulation frameworks, etc.). As an example, a simulator may provide for simulation of interactions between equipment and the environment, which may be in view of one or more field operations that may be performed according to one or more operational parameters. For example, drillstring simulation may be performed by a simulator where a drillstring is specified along with the environment and one or more drillstring operational parameters. In such an example, the environment may be specified in the form of a formation model. In various instances, simulation results may be more accurate when a formation model is more accurate (e.g., more closely resembles an actual environment). To help improve accuracy, a formation model may be calibrated. For example, consider a process that involves calibrating a formation model using information about an actual environment and/or an analog thereof to generate a calibrated formation model.

As an example, a framework may provide for generation of a calibrated formation model, which may be generated in a workflow that may include using field measurements. As an example, such a framework may provide for implementing a delta calibration approach that may include inversion formation properties. As an example, a delta calibration may be part of a workflow for generation of a calibrated formation model. As an example, a framework may provide for assessing equipment, selecting equipment, etc. For example, consider a framework that may provide for bit selection in a manner that may depend on one or more factors, which may include one or more factors related to a drillstring (e.g., BHA, etc.) and/or related to one or more formations.

Field measurements during actual drilling, may be matched with IDEAS simulations until a match between field measurements and simulations to generate a suitable formation model. In such an example, a simulator may be utilized to perform simulations. For example, consider one or more of the IDEAS family of drilling simulators. An article by Centala et al., entitled “Bit Design—Top to Bottom”, Oilfield Review, Summer 2011: 23, no. 2, is incorporated herein by reference in its entirety. The article by Centala et al., describes various aspects of simulation, including finite element analysis (FEA) simulation where an FEA mesh may be utilized to represent a modeled body such as, for example, a drillstring. The article by Centala et al., also describes a drill bit optimization system (DBOS, SLB, Houston, Texas) along with a DBOS formation characterization database that may be operatively coupled with a drilling simulation framework (e.g., IDEAS simulator, etc.). Additionally, the article by Centala et al., describes the i-DRILL engineered drilling system (SLB, Houston, Texas), which may utilize a drilling simulator (e.g., IDEAS simulator, etc.). As an example, an IDEAS simulator may utilize information in a rock file as input, which may be specific to a rock and cutter combination (e.g., formation and bit combination). As an example, a rock file may be a type of file that includes various types of information suitable for performing one or more drilling simulations using one or more drilling simulators.

As an example, a workflow may include accessing or generating an initial formation model for a particular location and then refining the initial formation model using acquired data (e.g., formation data, operational data, etc.). In such an example, a refined formation model may be referred to as a calibrated formation model. Given a calibrated formation model, one or more workflows may be performed. For example, consider a workflow that assesses bit characteristics, which may provide for improving bit selection, improving modeling of bit performance, etc.

As an example, an initial formation model may be accessed, generated, etc., using existing data as to one or more formations, one or more operations, etc. For example, consider data from offset wells that are offset from a location of a target well. In such an example, once data are acquired from operations at the target well, the initial formation model may be calibrated, which may be performed in an automated manner or a semi-automated manner. Such an approach may reduce reliance on one or more humans such that a formation model may be evergreened during field operations at a site with reduced demand on one or more domain experts. As an example, a calibrated formation model may provide for improved drilling operations at a site, which may be performed using a human driller, a controller, etc. As an example, a site may use an autodriller (AD) as a type of controller that may implement one or more levels of automated control for drilling.

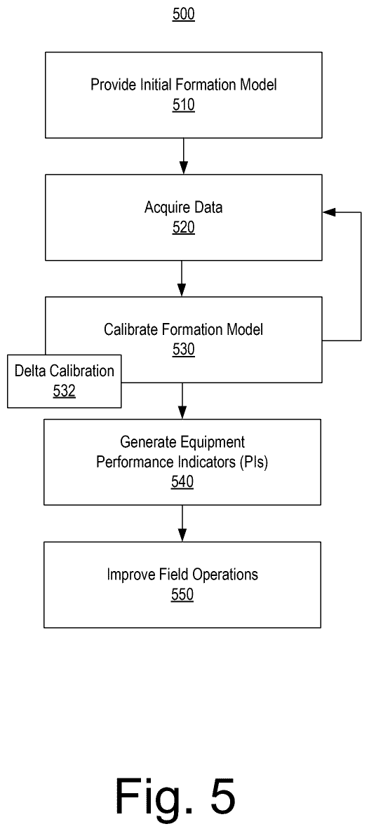

FIG. 5 shows an example of a method 500 that includes a provision block 510 for providing an initial formation model, an acquisition block 520 for acquiring data, a calibration block 530 for calibrating the initial formation model or another previously calibrated formation model, a generation block 540 for generating one or more equipment performance indicators (PIs), and an improvement block 540 for improving one or more field operations. As shown, the calibration block 530 may include or be operatively coupled to a delta calibration block 532. As shown, an iterative loop may exist between the calibration block 530 and the acquisition block 520 such that, if more data may be acquired, the method 500 may include performing one or more additional calibrations. In such an example, a calibrated formation model may be a version of multiple versions of calibrated formation models for a site. As mentioned, generation of PIs may depend on simulation results where, as explained, an improved formation model (e.g., a calibrated formation model) may provide for more accurate simulation results. As an example, one or more PIs may provide for decision-making as to one or more pieces of equipment where use of such one or more pieces of equipment may improve field operations (e.g., drilling, etc.).

As an example, a calibration may correspond to a depth or depth range. As an example, a borehole may be drilled in sections where each of the sections corresponds to a particular depth range. In such an example, one or more bits may be utilized with one or more drillstrings (e.g., BHAs, etc.). As an example, a calibrated formation model may provide for monitoring bit performance and/or selecting a bit. For example, after a bit has been selected and coupled to a drillstring to drill at least a portion of a section of a borehole, monitoring may include comparing expected performance to actual performance. In such an example, where deviations may occur, drilling may be controlled, for example, to address unexpected performance, whether positive and/or negative. As to positive, consider, as an example, actual wear being less than expected wear such that rate of penetration (ROP) may be increased via control. As to negative, consider, as an example, actual wear being greater than expected wear such that ROP may be decreased via control. As to selection of a bit, consider making a selection for a portion of a borehole to be drilled. In such an example, consider drilling a portion of a borehole using one bit, calibrating a formation model, and using the calibrated formation model to select another bit where that selected bit may be coupled to a drillstring to drill another portion of the borehole. As explained, a calibrated formation model may be utilized in one or more manners to improve drilling.

As an example, a framework may provide for new bit selection. As an example, a framework may provide for considering one or more scenarios. As explained, a framework may provide for monitoring and/or control of drilling operations.

As an example, a framework may include or be operatively coupled to one or more simulators. For example, consider a drilling simulator such as one or more of the family of IDEAS simulators. As an example, a simulator may provide for predicting downhole behavior of a drillstring where simulation results may help to deal with one or more types of drilling challenges. As an example, a simulator may depend on a formation model such that interactions between a drillstring and formation may be simulated. In such an example, the simulation results may depend on accuracy of the formation model. Accordingly, use of a calibrated simulation model by a simulator may provide for generation of more accurate simulation results. For example, to help improve accuracy of simulation results, a formation model may be calibrated in advance to more closely replicate a real scenario.

As an example, a formation model may be built, accessed, etc., for a site of interest (e.g., a subsurface region). As an example, a database may be accessed that may include various formation models, which may be utilized as initial models, editable models, etc. Such formation models may include offset well formation models, which may be in a common field and/or in an analogous region. As an example, a framework may provide for generation of calibrated formation models according to a particular schema. For example, consider a schema that may provide for some amount of standardization for various regions (e.g., sites) such that calibrated formation models may be archived, published, accessed, etc., for one or more purposes (e.g., workflows, controls, etc.).

As an example, a calibrated formation model for a simulator may be defined according to a schema that specifies particulars as to one or more of a rock file, a rock multiplier, a tortuosity setting, an inhomogeneity pattern, damping behavior, etc. As an example, a schema may provide for specifying one or more aspects as to context. For example, consider context as a form of reference, which may include one or more of trajectory, wellbore geometry, mud, BHA, bit, etc. As an example, calibrated formation models may be centralized on generation for archiving, publishing for downstream consumption, etc.

As an example, a calibrated formation model repository (e.g., database, etc.) may provide for improved consistency, expediting workflows, improved drilling, etc. Such an approach may supplant a more siloed approach where formation models may be generated and maintained by one or more individuals in association with a particular site (e.g., for local application), where a common schema may be lacking. As an example, a framework may provide for unifying formation models using a common template (e.g., schema, etc.) where a repository may provide for access, publishing, etc. In such an approach, given a sufficient number of formation models in a repository, a method such as, for example, the method 500 of FIG. 5 may including accessing the repository for an initial formation model (e.g., as a closest analogue, whether a nearby offset well or a remote well) and then archiving one or more calibrated formation models in the repository.

As an example, calibrated formation models may be substantially unified and centralized, which may provide for support of one or more workflows. As explained, a workflow may include a bit selection workflow. As explained, in various instances a simulator may be utilized whereby a formation model and a bit may be specified such that the simulator may simulate interactions between the bit and formation; noting that the bit may be coupled to a drillstring and/or may be part of a BHA, where a simulator may account for the drillstring and/or the BHA. As an example, a framework may provide for computation of performance indicators (PIs) as part of a workflow where the PIs may pertain to bit performance. In such an example, the framework may provide for bit selection. As an example, a framework may provide for integrating new bit designs, new BHA designs, etc., such that, for example, a bit may be appropriately selected (e.g., with or without a particular BHA design, etc.).

As an example, a framework may consume one or more calibrated formation models as part of one or more scenarios, which may provide for improved bit selection. In such an example, the framework may provide for calibrating one or more formation models, for example, by providing or accessing an initial formation model and accessing data to calibrate the initial formation model, followed by, for example, using the calibrated formation model for one or more simulations of bit and formation interactions (e.g., bit performance, etc.). Such an approach may be an automated approach that may automate a calibration process to compute PIs to select one or more bits for drilling at a site amongst a number of bits. As an example, calibrated formation models may be generated and consumed via a workflow, automatically.

As explained, a framework may provide for implementation of a delta calibration technique. Such a technique may facilitate calibrating a formation model, which may then be utilized for one or more purposes (e.g., simulation, bit selection, control, etc.). As explained, a simulator may utilize a calibrated formation model for simulating bit and formation interactions, which may help to characterize bit performance with respect to bit design, drilling operations, borehole trajectory, etc.

As explained, a simulator may be or include a drilling simulator (e.g., one of the IDEAS family of drilling simulators, etc.) and may be utilized to simulate downhole behavior of bit and formation interactions where simulation results may provide for addressing various drilling challenges. As explained, simulation results may be more accurate where a formation model is more accurate. As explained, a framework may provide for automated calibration where, for example, responsive to a trigger, data may be accessed and a calibration workflow performed. Such an approach may reduce involvement of a human-in-the-loop (HITL) as to domain experience (e.g., expertise, knowledge of simulator operation, familiarity as to local formation, etc.).

As an example, a delta calibration technique may provide for calibrating one or more parameters of a formation model. For example, a formation model may include parameters such as, for example, one or more parameters relating to tortuosity, damping, inhomogeneity, rock type, friction, etc. As an example, a delta calibration technique may provide for automated calibration of a set of parameters, which may include, for example, a rock multiplier, one or more fraction factors, etc. As an example, a delta calibration technique may provide for calibration of a formation model by calibrating fewer than all of the parameters of the formation model. As an example, a delta calibration technique may provide for identifying one or more parameters to be calibrated where, for example, such one or more parameters may be relevant to simulation of bit and formation interactions. As an example, a delta calibration technique may provide for expediting calibration of a formation model, for example, by calibrating fewer than all parameters of the formation model. In such an example, complexity of calibration may be reduced. As explained, scenarios may be formulated where performance indicators (PIs) may be computed for each scenario and, for example, compared to improve drilling, whether via planning, re-planning, control during actual drilling, selection of one or more bits, etc.

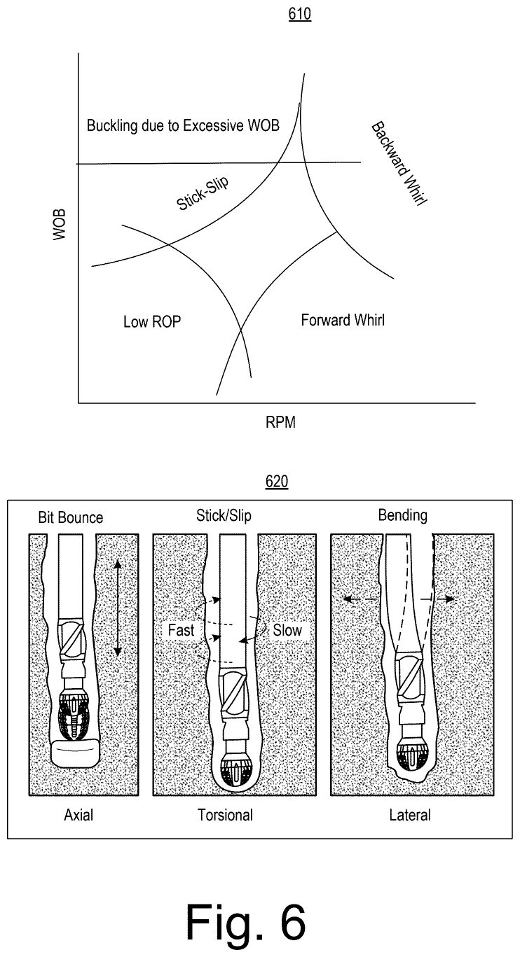

FIG. 6 shows an example plot 610 of WOB versus RPM for drilling, where an optimal region may be defined with respect to one or more types of issues or challenges, and a series of graphics 620 that illustrate some examples of issues or challenges. As shown in the plot 610, an excessive WOB may lead to buckling of a drillstring or stick-slip behavior while too low WOB may lead to low ROP or forward whirl. As shown, backward whirl may occur where RPM is above a particular level for a range of WOB values. As a goal of drilling may be to achieve an optimal ROP, where WOB and RPM are too low, such an optimal ROP may be unachievable, however, drilling at a low ROP may be relatively free of issues. As indicated, a combination of WOB and RPM may be selected to optimize drilling.

In FIG. 6, the series of graphics 620 illustrate bit bounce as an axial phenomenon (e.g., axial motion), stick-slip (or stick/slip) as a torsional phenomenon (e.g., torsional oscillations), and bending as a lateral phenomenon (e.g., lateral shock). As mentioned, whirl may be a phenomenon that may be directional (e.g., forward or backward) and cause a drillstring to be eccentered. Such phenomena may depend on equipment, operation of equipment, and formation characteristics. Dynamic downhole conditions may be challenging to identify, characterize, etc., and, at times, may be assumed to be of one type or another by one or more individuals at a site.

As explained, a simulator may utilize a formation model that characterizes a formation, which may include one or more layers. Such a simulator may provide for generating simulation results that may provide for identifying, characterizing, etc., one or more types of behaviors, drilling performance, borehole quality, etc. A simulator may be implemented to predict, identify, analyze, etc., behaviors prior to, during, and/or after drilling.

A simulator may utilize a 3D model of an entire drillstring with a BHA and a bit to simulate bit and rock interactions, which may give rise to vibration, stress, force, etc., with multiple degrees of freedom (DOF) (e.g., consider 6 DOF). A simulator may generate results that may provide for prediction of bit and BHA performance. A simulator may find use by a bit designer (e.g., to certify a design), a product engineer (e.g., for performance), a post-analysis engineer (e.g., drilling assessment, optimization, etc.).

As an example, input to a simulator may include information as to cutting structure, BHA components (e.g., model, size, parameters, etc.), well (e.g., profile, measured depth (MD), inclination, azimuth, etc.), casing string, operational parameters (e.g., depth, WOB, RPM, flow rate, etc.), rock (e.g., rock type, strength, properties, etc.), stratification (e.g., homogeneous, inhomogeneous, etc.). As to rock and stratification, these aspects may be provided as part of a formation model. As an example, output of a simulator may include information as to bit torque, surface torque (STOR), WOB and RPM sensitivity, etc. As explained with respect to the plot 610 of FIG. 6, optimal drilling may involve selecting appropriate WOB and RPM values.

As to field measurements, data may be acquired as to surface measurements (e.g., HKLD (SWOB), ROP, SRPM, STOR, flow rate (FLWI), standpipe pressure (SSP), etc.) and downhole measurements (e.g., axial acceleration, lateral acceleration, stick-slip, downhole torque (DTOR), etc.), where data sources may provide for one or more of run-based data, depth-based data, time-based data, etc.

As an example, a workflow may aim to calibrate measurements by adjusting input to a simulator. For example, consider an inverse technique where a formation model may be calibrated by running a simulator in an iterative manner until a suitable match is achieved between field data and simulation results by making adjustments to the formation model. In such an approach, once a suitable match is achieved, it may be assumed that the formation model is suitably accurate as its use by the simulator may generate simulation results that are sufficiently close to actual field data (e.g., as to drilling behavior, etc.).

As an example, an inverse technique may provide for calibration of a rock file, a friction factor, etc. Such an approach may make a simulation more accurate and tailored to a particular actual scenario, which may impact one or more aspects of drilling (e.g., bit selection, BHA selection, etc.). As an example, an automated and, for example, standardized, approach may be implemented by a framework that may provide for expedited science-based improvements to drilling, which may include improvements as to control, component selection, failure analysis, etc.

As an example, a calibrated formation model may be deduced from field data (e.g., field measurements) using an inversion technique involving simulation. Such an approach may involve utilization of scenarios where a particular scenario may be deemed to be a best match to an actual scenario to understand better bit and formation interactions, which may involve aspects of a drillstring other than just a bit (e.g., consider BHA characteristics, etc.). As an example, a calibrated formation model may be utilized to predict behavior for hypothetical scenarios that may involve utilizing a different bit, a different BHA, one or more different operational parameters, etc. For example, once a calibrated formation model is generated, that calibrated formation model may be utilized in one or more simulations to gain insights as to drilling at a site that may provide for improved drilling at the site.

As an example, a formation model may include a rock file or rock files. Such a file may provide for capturing bit cutter and rock interactions. A rock file may include information derived via experiments and/or field data. As an example, a rock file may be based at least in part on variations in depth, back rake (BR), and side rack (SR). As an example, a cutter may be a component of a bit that includes a number of cutters, which may be of differing size, shape and/or material. As an example, data may include operational data as to depth, BR, and SR for different cutters, and different types of rock, where confining pressure may be varied (e.g., 3000 psi, 6000 psi, 9000 psi, etc.). Output from such experiments may be organized in the form of a rock file, which may be part of a formation model. As an example, a formation model may also include properties as to tortuosity setting, damping coefficients, homogeneity or inhomogeneity, interbedded rock, inclusion rock, friction dependence on speed, rock type, etc. As to friction and speed, friction and/or types of friction may vary in a manner dependent on velocity. For example, a friction profile may be generated with respect to velocity where the friction profile may include a breakaway friction, a Stribeck friction, a Coulomb friction, a stiction friction, a viscous friction, etc. As explained, a formation may be layers in an inhomogeneous manner and/or include inclusions.

As an example, a formation model may include or be associated with a context. For example, context may include information as to trajectory, wellbore geometry, mud (drilling fluid), BHA, bit, etc. Such information may be embedded in a formation model as contextual information for purposes of simulation, for example, to restore field measurements via simulation. As explained, an inverse technique may aim to adjust one or more physical aspects of a formation model such that a suitable match is achieved between field measurements (e.g., field data) and simulation results. As a simulator may be a drilling simulator, context may provide for knowing how a scenario (e.g., drillstring, borehole, etc.) relate to a formation as characterized by physical aspects of a formation model. Where a formation model includes contextual information, it may be understood how that formation model may have been calibrated such that one or more scenarios that may have similarities in context may provide for some indication as to how good that formation model may be for such one or more scenarios. In such an approach, calibration may be focused on one or more aspects that pertain to one or more differences in context (e.g., between a calibration scenario and another scenario, etc.).

As an example, a formation model may include information as to trajectory, wellbore geometry, BHA (e.g., BHA components, etc.), bit and formation. As explained, some information may be as to physical aspects of a formation and other information may be contextual.

As explained, a calibrated formation model may be utilized to predict behavior for drilling at a site, which may be for current equipment and/or operational parameters and/or for hypothetical equipment and/or operational parameters.

As an example, a workflow may include receiving field measurements and contextual information where the field measurements may include, for example, one or more of SROP, STOR, differential pressure (DiffP), downhole lateral acceleration, downhole axial acceleration, downhole stick-slip, etc., and where the contextual information may include, for example, one or more of well information, BHA, sample depths, SWOB, SRPM, flow rate (FLWI), etc. In such an example, the workflow may provide for formation model calibration where the formation model may include a rock file and a multiplier (e.g., a rock multiplier), a friction factor, a damping coefficient, one or more zones, a critical depth, etc. As an example, a simulator may utilize information in the formation model to generate simulation results, which may include, for example, one or more of instant ROP, instant TOR, instant WOB, instant RPM, lateral acceleration, axial acceleration, stick-slip, dogleg severity, etc. As an example, a simulator may provide for simulation as to one or more scenarios, which may be assessed for one or more purposes.

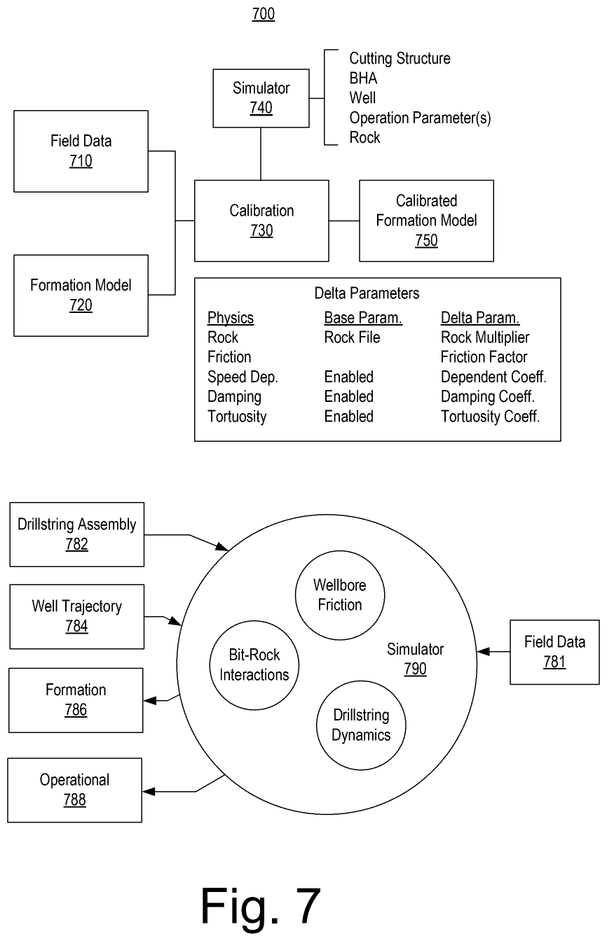

FIG. 7 shows an example of a system 700 where field data 710 and a formation model 720 may be received for calibration 730 using a simulator 740 to generate a calibrated simulation model 750. As explained, a delta approach may be implemented, which may include calibration of a number of parameters. As shown, parameters may pertain to particular physics where one or more base parameters may be identified along with one or more delta parameters. For example, a rock file may include a rock multiplier and, for example, a friction factor may be speed dependent. As indicated, damping and/or tortuosity may be considered where such physical phenomena may be characterized using one or more coefficients.

FIG. 7 also shows an example of a simulator 790 that may provide for simulation of wellbore friction, bit-rock interactions, and drillstring dynamics based on input that may include input as to field data 781, a drillstring assembly 782, and a well trajectory 784, where output may include formation information 786 and operational information 788 (e.g., dynamics, etc.). In such an example, the simulator 790 may provide for drilling dynamics simulations that may include non-linearities and that may utilize one or more discrete rock files. As shown, drillstring assembly details may be utilized for performing simulations, which may specify bit, mud motor, extension sub, jetting assembly, bent sub, collar, etc., characteristics for one or more drillstring assemblies. As to formation outputs (e.g., simulation results, etc.), these may include open-hole friction factor, casing-hole friction factor (e.g., cased hole friction factor), one or more rock file characteristics, one or more indicators as to inhomogeneities, etc. As to operational outputs (e.g., simulation results, etc.), these may include one or more damping coefficients, one or more speed dependent friction parameters, one or more speed dependent torque parameters, etc. As explained, results may be utilized for one or more purposes, which may include selection of equipment, characterization of subsurface material, control of one or more operational parameters for drilling operations, etc.

As an example, a formation model workflow may include performing a calibration process for calibrating a formation model (e.g., rock file, multiplier, friction factor, damping coefficient, homogeneous/inhomogeneous regions, critical depth(s), etc.) to generate a calibrated formation model that may be utilized in performing one or more simulations (e.g., drilling simulations where a drill bit interacts with rock). In such an example, one or more simulations may provide simulation results that include and/or that may be utilized to computer instantaneous ROP, torque, WOB, RPM, etc., lateral acceleration, axial acceleration, stick-slip, dogleg severity, etc. As an example, multiple simulations may be performed for various scenarios where, for example, operational parameters may be compared (e.g., consider comparing lateral acceleration, etc.). Such an approach may provide for control of drilling operations in a manner that improves drilling and/or a resulting borehole as a physical product of drilling.

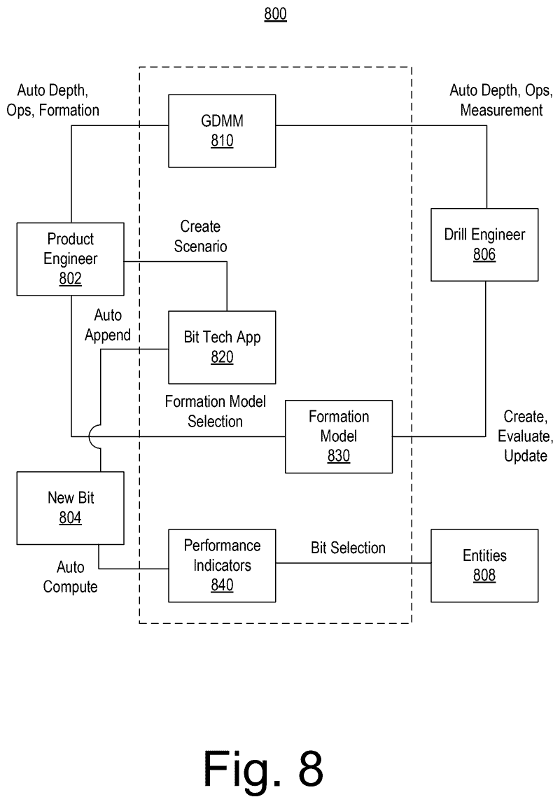

FIG. 8 shows an example of a system 800 that may include a global data model management (GDMM) database 810, a bit technology application 820, a formation model component 830, and a performance indicators (PIs) component 840. As shown, various entities 802, 806, and 808 may interact with the system 800, for example, to assess a new bit 804, which may provide for bit selection for the entity 808.

As explained, a framework may provide for decision-making as to one or more pieces of equipment. While the example system 800 refers to a bit or bits, as an example, such a framework may provide for selection of one or more other types of equipment, additionally and/or alternatively. As explained, a framework may operate in an automated manner as to one or more processes. For example, consider a framework that may provide for an evergreen approach whereby new equipment may be integrated into a workflow such that new equipment may be considered in a decision-making (e.g., a selection) process.

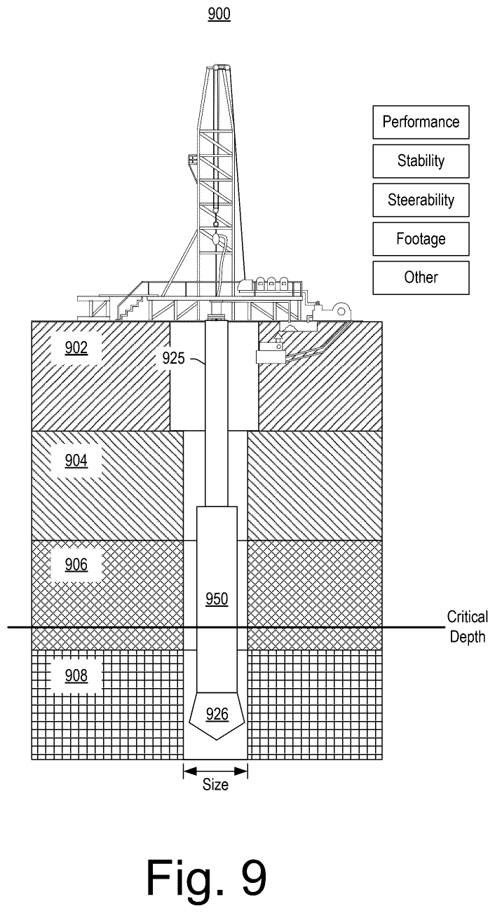

FIG. 9 shows an example of a system 900 that includes a series of layers 902, 904, 906, and 908 where a drillstring 925 is in a borehole where the drillstring 925 includes a BHA 950 and a bit 926. Drilling operations using the system 900 may pertain to performance, stability, steerability, footage, and/or one or more other types of characteristics. In the example of FIG. 9, a critical depth is indicated as being in the layer 906. As shown, the critical depth is for a portion of the borehole with a particular size (e.g., diameter), noting that a borehole may be drilled in sections where section diameter decreases with respect to depth (e.g., MD). As a borehole becomes longer, drilling may become more challenging for one or more reasons. In various instances, drilling aims to reach a target, which may be a reservoir and/or a location in a reservoir. In various instances, a borehole may be drilled a distance within a reservoir to increase reservoir contact (e.g., for producing fluid from the reservoir, injecting fluid into the reservoir, etc.).

As an example, a formation model may include metadata as to location, depth, formation name, formation type, unconfined compressive stress (UCS), interval profile, primary drive type, and/or mud type; formation properties as to rock (e.g., rock file, rock multiplier, etc.), inhomogeneity (e.g., none, interbedded, inclusion, etc.), friction (e.g., cased hole, open hole, etc.), speed effect (e.g., bit torque, friction, etc.), and/or one or more other(s); and a calibration context as to trajectory, wellbore geometry, BHA, mud, bit, and operational information (e.g., depth, WOB, ROP, RPM, STOR, drilling mode, etc.).

As explained with respect to the example system 800 of FIG. 8, a bit tech application (see, e.g., the bit tech app 820) may be utilized; noting that one or more types of bit tech apps may be utilized. As an example, a bit tech app may operate using various types of data, which may include metadata, scenario specifications, sensitivity information, etc. As to metadata, consider, for example, location, size range, formation name, drilling interval, drive type, bill of material for a bit (BOM), etc. As to scenario specifications, consider, for example, plan context (e.g., trajectory, wellbore geometry (WBG), BHA, mud, etc.), formation model (e.g., rock file, friction factor, etc.), depth selection (e.g., depth1, depth2, etc.), operation range (e.g., WOB (min, mean, max), etc.), mode selection (e.g., steering, neutral, etc.), equipment selection (e.g., bit selection from candidates such as Bit1, Bit2, Bit3, etc.), etc. As to a sensitivity analysis, consider, for example, formation sensitivity (e.g., rock multiplier (0.8, 1.2), etc.), BHA sensitivity (e.g., bent angle (−0.1, +0.1), etc.), etc.

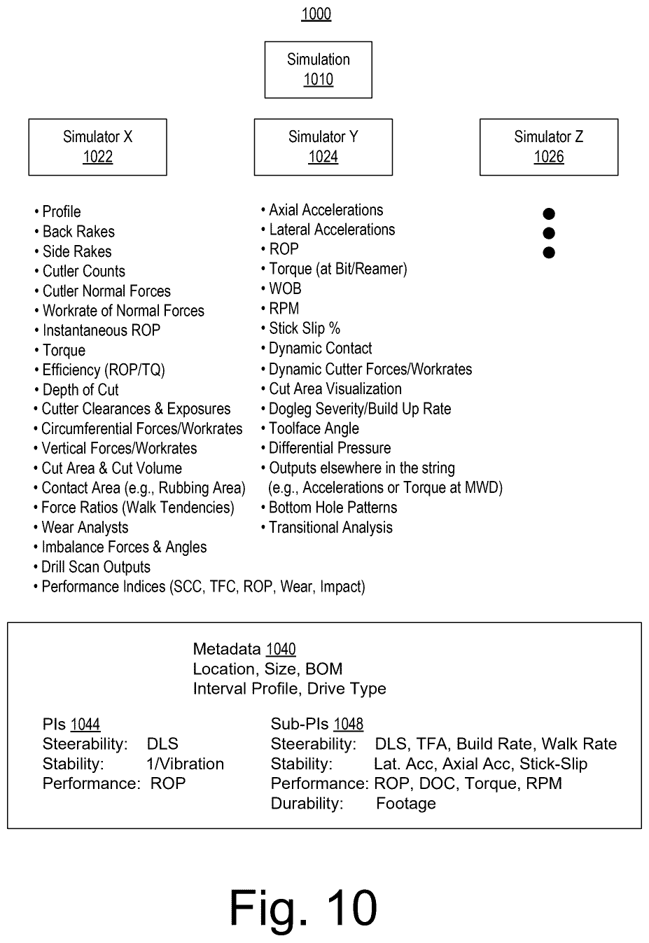

FIG. 10 shows an example of a system 1000 that may provide for performing one or more simulations 1010 using one or more simulators such as a simulator X 1022, a simulator Y 1024, a simulator Z 1026, etc. As shown, simulators may differ, for example, the simulator X 1022 may provide for generation of static results while the simulator Y 1024 may provide for generation of dynamic results. As shown, the simulator X 1022 may provide for output of various results, which may include one or more of the types of results output by the IDEAS1 simulator while the simulator Y 1024 may provide for output of various results, which may include one or more of the types of results output by the IDEAS3 simulator. As shown, static results may include cutter normal forces, instantaneous ROP, torque, efficiency (e.g., ROP/torque), depth of cut (DOC), etc. As shown, dynamic results may include axial accelerations, lateral accelerations, stick-slip, etc.

As explained, a framework may provide for generation of PIs that may include one or more simulation results-based PIs. In the example of FIG. 10, some examples of metadata 1040, PIs 1044 and sub-PIs 1048 are shown. As explained, a framework may provide for generation of PIs according to a hierarchy that may include PIs and sub-PIs. In the example of FIG. 10, the system 1000 may include a framework and/or be operatively coupled to a framework that may consume simulation results to provide for computation of PIs such as, for example, the PIs 1044 and the sub-PIs 1048, which may correspond to particular metadata such as, for example, the metadata 1040.

As shown in the example of FIG. 10, the PIs 1044 may pertain to steerability (e.g., with respect to DLS), stability (e.g., with respect to vibration), and performance (e.g., as ROP, etc.). As shown, the sub-PIs 1048 may include steerability sub-PIs, stability sub-PIs, performance sub-PIs, durability sub-PIs, etc. As an example, decision-making as to a bit may depend on one or more PIs (e.g., at one or more levels of a hierarchy, etc.).

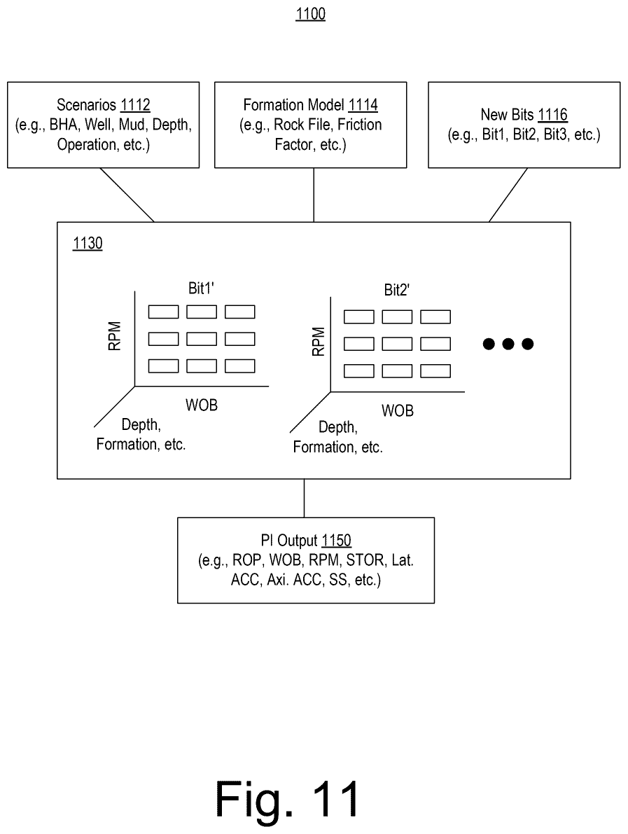

FIG. 11 shows an example of a system 1100, which may be a bit tech app system, that includes a scenarios block 1112 for providing scenario information (e.g., BHA, well, mud, depth, etc.), a formation model block 1114 for providing a formation model (e.g., rock file, friction factor, etc.), and a new bits block 1116 for providing information as to bits (e.g., Bit1, Bit2, Bit3, etc.). As shown, a block 1130 may provide for formulating scenarios as to RPM, WOB, etc., for considering various bits where such scenarios may be utilized by the block 1130 to generate results that characterize the various bits, which may include simulation results. As shown, an output block 1150 may provide for outputting one or more PIs.

As an example, a framework may provide for receipt of input that may include new equipment (e.g., new bits, etc.), scenarios (e.g., well, BHA, operation, formation, etc.), and one or more sensitivity options (e.g., BHA, formation, etc.). As an example, a framework may provide for execution of one or more processes using resources of a cloud platform (e.g., simulation case generation, resource provisioning, submission to provisioned resources, storage of results, etc.). As an example, a framework may provide for computation of one or more PIs, which may include using statistical techniques, probabilistic techniques, etc. (e.g., statistics with respect to depth, operations, etc.). As an example, a framework may provide for storage of one or more PIs, which may be stored in association with one or more other types of data (e.g., metadata, etc.).

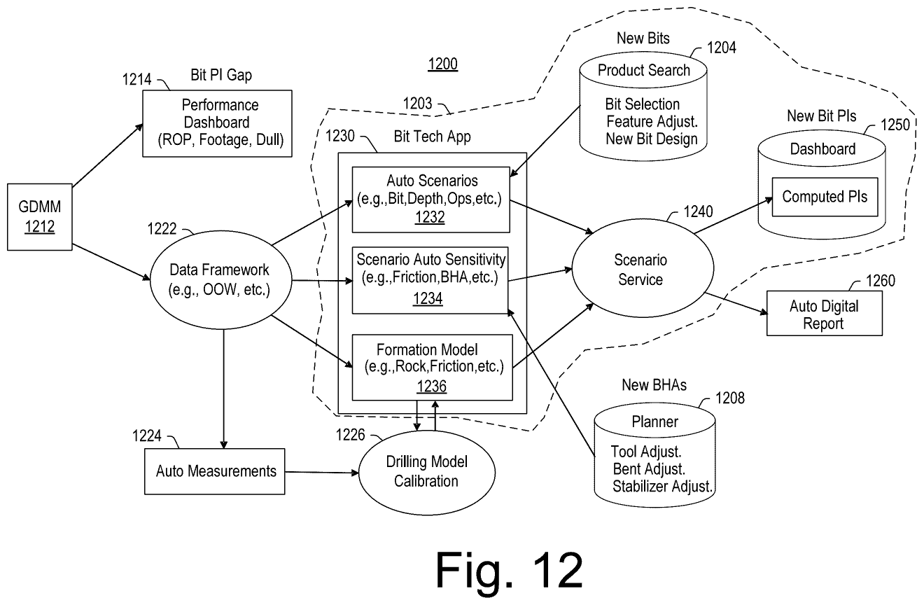

FIG. 12 shows an example of a system 1200 that may include or be operatively coupled to an equipment selection framework, which may include one or more components within the dashed line labeled 1203. For example, consider an equipment selection framework that may include a bit technology application 1230.

As an example, the system 1200 may include or be operatively coupled to a formation model framework, which may include a drilling model-based calibration component 1226 that may receive measurements automatically extracted by an auto measurement component 1224 that may be part of or operatively coupled to a data framework 1222.

As shown, the bit technology application 1230 may include various components such as, for example, an automated scenario generation component 1232, a scenario automated sensitivity component 1234, and a formation model 1236 component (e.g., for accessing and using one or more formation models). As indicated, the bit technology application 1230 may receive information from various sources, which may include the data framework 1222, a new bit product search component 1204, and a new BHA planner component 1208. As indicated, a scenario service 1240 may operate using output of the bit technology application 1230 for computing scenario-based performance indicators (PIs) that may be rendered to a dashboard via a component 1250 and/or that may be part of an automatically generated digital report 1260.

In the example of FIG. 12, the system 1200 may include a GDMM component 1212 that may provide for transmitting information to the data framework 1222 and/or provide for generating information for one or more gaps in performance indicators (PIs) for a bit or bits per a bit PI-based gap component 1214. For example, consider a performance dashboard that may provide for rendering one or more bit PI-based gaps. As an example, the component 1214 may be integrated with or operatively coupled to the component 1250. In such an approach, a user may interact with a dashboard to visual performance gaps that may be addressed via one or more changes to equipment (e.g., a different bit, a different BHA, etc.), which may be based at least in part on a calibrated formation model.

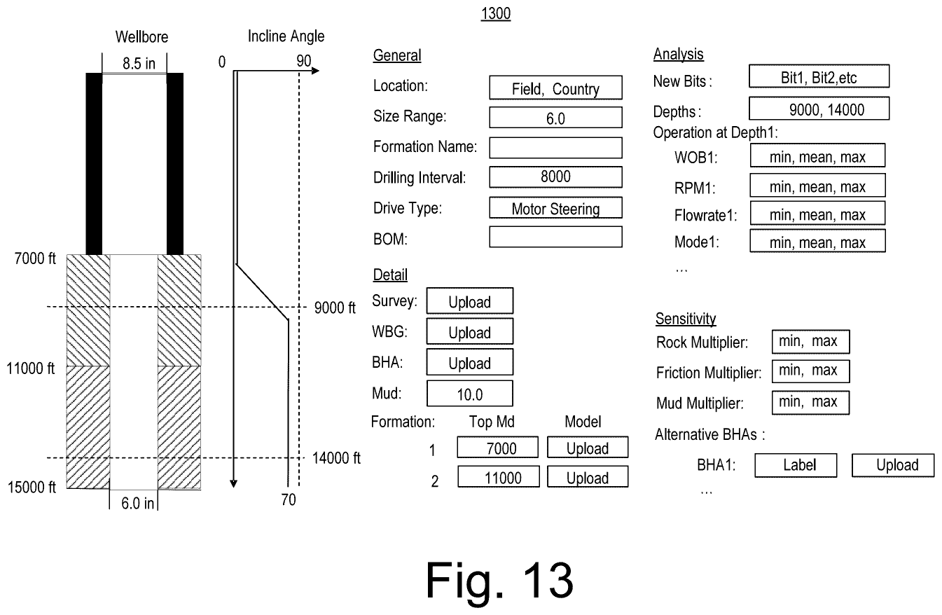

FIG. 13 shows an example of a graphical user interface (GUI) 1300 that includes various graphics, fields, etc., as may be associated with an equipment selection framework. As shown, information as to a wellbore may be provided, which may include section specifications, formation specifications, incline angles (e.g., dogleg severity, etc.). As shown, information may be provided with respect to depth, which may range hundreds to thousands of feet, hundreds to thousands of meters, etc. As shown, the GUI 1300 includes features for general information, detailed information (e.g., including survey, WBG, BHA, mud, formation, etc.), analysis information (e.g., bits, depths, operational parameters, etc.), and sensitivity information (e.g., rock multiplier, friction multiplier, mud multiplier, alternative BHA(s), etc.).

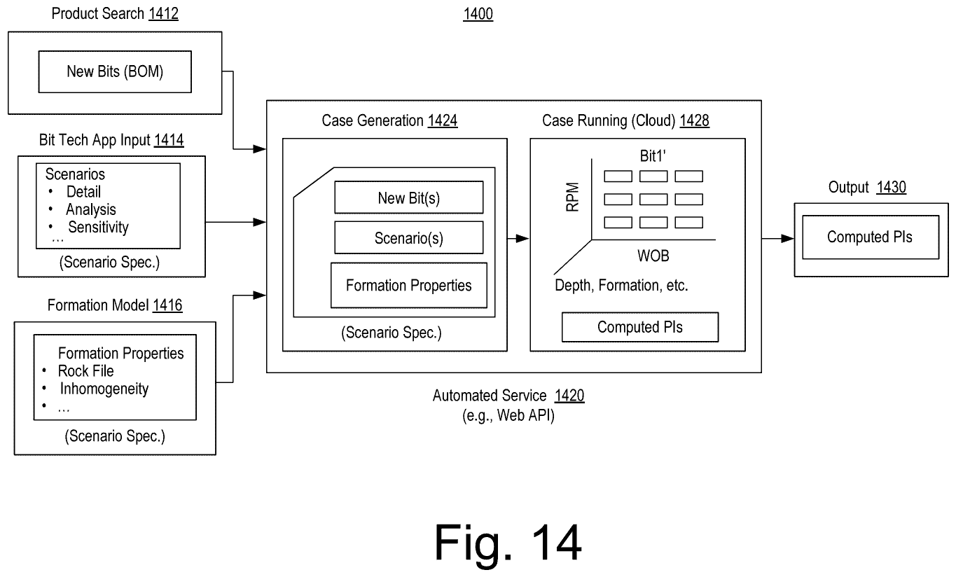

FIG. 14 shows an example of a system 1400 that includes various inputs, for example, from a product search component 1412, for a bit technology application 1414, and a formation model 1416. Such inputs may provide for formulation of various scenarios, for example, by an automated service 1420 (e.g., a Web application service, etc.) where the automated service 1420 may provide for generation of output, as indicated by an output component 1430, which may output one or more PIs.

As shown, the automated service 1420 may include a case generation component 1424 that may provide for defining scenarios for new bits, formation properties, etc., where, for example, a case execution component 1428 that may provide for generation of simulation results that may be a basis for computations as to one or more PIs. As explained, computed PIs may be output by the output component 1430, which may be operatively coupled to one or more visualization components, for example, for GUI generation, etc. While the example of FIG. 14 refers to bits, as an example, a system such as the system 1400 may provide for generation of PIs for one or more other types of equipment, additionally and/or alternatively.

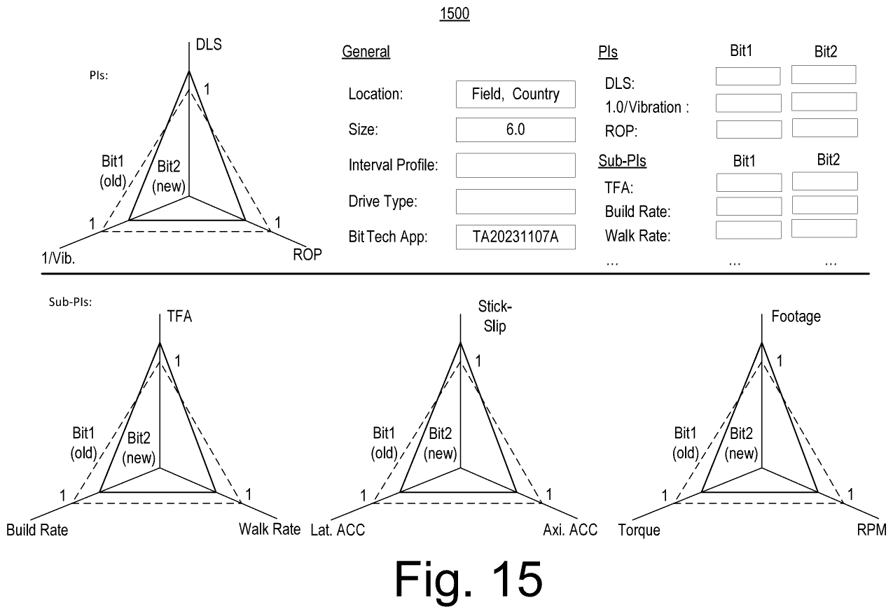

FIG. 15 shows an example of a GUI 1500 that includes various graphics, fields, etc. As shown, one or more spider plots may be generated and rendered, which may correspond to one or more PIs, which may be according to a hierarchy. As shown, a spider plot may include multiple axes for different PIs such as, for example, DLS, 1/vibration, and ROP where, for example, PIs for different bits (e.g., different equipment) may be plotted to provide for visual comparisons of performance for the different bits. Other spider plots may include, for example, a TFA, build rate, and walk rate plot, a stick-slip, lateral acceleration, and axial acceleration plot, and a footage, torque, and RPM plot.

As explained, a framework may utilize a schema or other type of specification as to data structures, etc. For example, consider a schema suitable for implementation using JSON, etc.

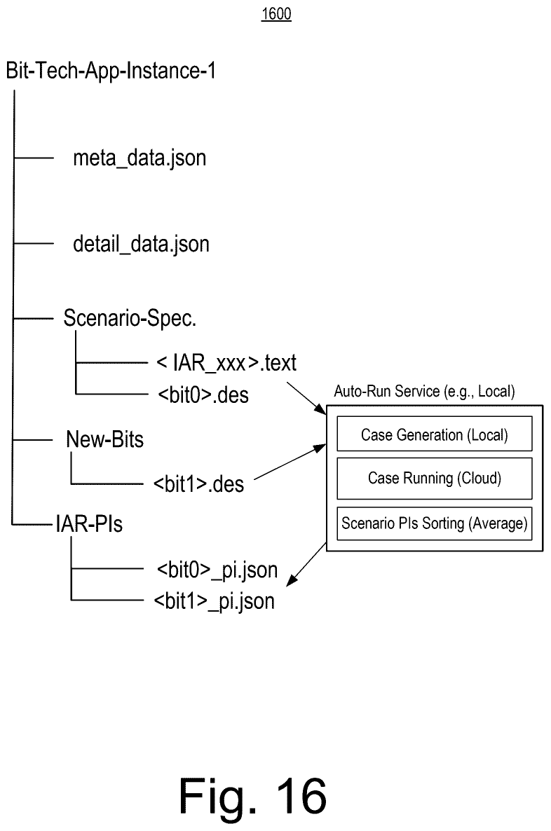

FIG. 16 shows an example of a schema 1600 for a bit technology application instance. As shown, an instance may be structured using the schema 1600 to include metadata, details, scenario specifics, new bits, and scenario (e.g., IAR) PIs. As shown, various features of the schema 1600 may facilitate automation. For example, consider the automated service 1420 of FIG. 14 where the case generation component 1424 and the case execution component 1428 may be features of the automated service 1420. As shown in the example of FIG. 16, the auto-run service may be a local service that may provide for local case generation using scenario specifics (e.g., specifications, etc.) and new bit information where cases (e.g., scenarios) may be executed using cloud-based resources (e.g., one or more cloud-based simulators, etc.), such that scenario PIs may be generated and, for example, appropriately sorted for organizing according to the example schema 1600. For example, scenario PIs may be organized on a per-equipment basis where, for example, equipment may be bits such that each bit has its own PI JSON data structure. In such an example, the schema 1600 may facilitate automation and/or workflow processes, which may include generation of one or more GUIs where, for example, one or more PIs may be visualized to facilitate review and/or decision-making as to equipment. Such an approach may provide for automation at one or more points that may help to expedite decision-making as to equipment for field operations, which, in turn, may help to expedite, improve, etc., field operations.

As shown, the schema 1600 may include a metadata structure (e.g., meta_data.json), which may include, for example, expressions such as the following:

{“location”:”XXY-Well1”, “size-range”: “6.0-6.25”, “formation-name”:
“ZZX”, “drilling-interval”: “8000-ft”, “interval-profile”: “vertical-curve”,
“drive-type”: “Motor”, “BOM”: “67826A0201”}

As shown, the schema 1600 may include a details structure (e.g., detail_data.json), which may include, for example, expressions such as the following:

“survey”: [[0, 0, 0], [2000, 0, 0], [3000, 90, 0]],
“Wellbore-geometry”: [12.25, 0, 3000], [8.5, 0, 7000], [6.0, 7000, 6000]],
“string”: [...],
“mud”: 10.0,
“formation”: [{“top-md”: 7000, “formation model id”: “formation model
id 20231221112”, “top-md”: 11000, “formation-model-id”:
“formation-model-id- 20231221112”,}],
“new-BOMs”: [“68598A0001”, “6851260001”, “68593A0001” ],
“operations”: [
{“depth”: 9000, “weight-on-bit”: [20, 40], “surface-RPM”: [100, 140],
“flowrate”: [300, 600], “steering-ratio”: [1.0, 0.0]},
{“depth”: 14000, “weight-on-bit”: [20, 40], “surface-RPM”: [100, 148],
“flowrate”: [300, 600], “steering-ratio”: [1.0, 0.0]}
],
“sensitivity-options”: “none”,
“sensitivity-parameters”: {“rock multiplier”: [0.8, 1.2], “friction
multiplier”: [0.8, 1.2],

As explained, a framework may utilize a schema that facilitates access, workflow performance, etc. As explained, a schema may be provided that may utilize a particular language such as, for example, JSON or another suitable language. As an example, multiple languages may be utilized (e.g., consider using JSON, PYTHON, etc.).

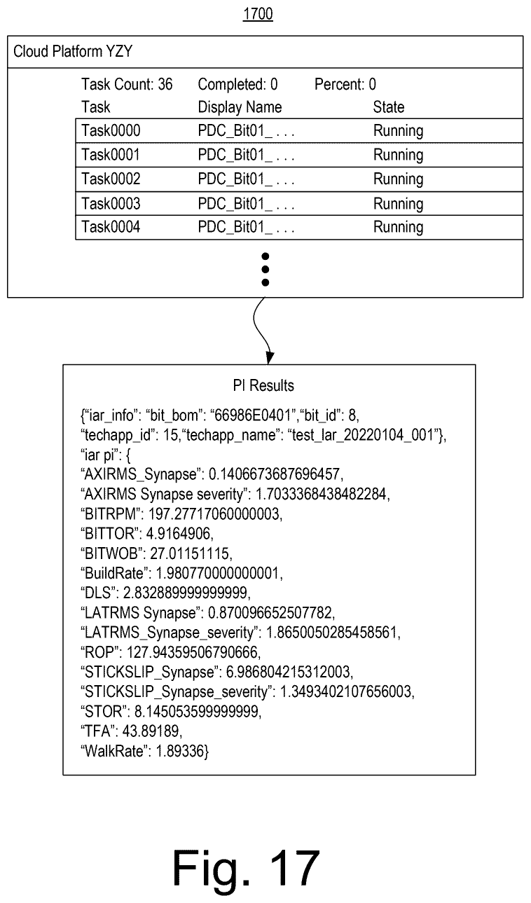

FIG. 17 shows an example of a GUI 1700 that includes various fields related to execution of tasks in a cloud environment. For example, the GUI 1700 may be operatively coupled to the case execution component 1428 of the automated service 1420 of FIG. 14. In such an example, cases may be run as tasks whereby an individual may track execution of the tasks, as may related to a decision-making process for equipment to perform one or more field operations. As shown, the GUI 1700 may include a task count, completion information, etc. As an example, an individual task may have an associated moniker, display name, state, etc.

In the example of FIG. 17, some examples of organized output are shown, as may be based at least in part on execution of the tasks, which may include, for example, one or more simulation tasks (e.g., drilling simulation, etc.), one or more data assessment tasks, etc. As shown in the example of FIG. 17, the output may be or include PI results. For example, a scenario may be associated with a bit BOM, which may be a number, etc. As explained, one or more simulators may be utilized to generate simulation results as to behavior of a bit within an environment (e.g., a formation, etc.). As shown, results may be generated for one or more defined PIs, which may be part of a hierarchy. In the example of FIG. 17, the PI results may be organized as a data structure that may be part of a schema such as, for example, the schema 1600 of FIG. 16. As explained, a schema may provide for expedited generation of visualizations for one or more GUIs, etc., and/or for consumption by one or more frameworks for performing one or more workflows, etc.

As an example, a framework such as the SYNAPSE framework (SLB, Houston, Texas) may be utilized. Such a framework may utilize data from a memory-mode shock and vibration logging tool located inside a bit (e.g., PDC bits, roller cone bits, etc.). Such a framework may provide for assessment of run data to evaluate drilling system performance, for example, via measurements as to 3-axis acceleration, torsional vibration, and rpm. Such data may provide an improved understanding of downhole events, identify performance limiters, etc. As an example, the SYNAPSE framework may provide for characterizing bit performance (e.g., bit behavior) as exhibited during drilling operations. As an example, an assessment may provide for development and adjustment of drilling parameters, further optimizing drilling performance for improved overall efficiency while downhole, etc. As an example, acquired data may help to reduce premature tool failure, direct tool maintenance systems, evaluate performance of new motor designs, optimize the bit selection, etc. As an example, the SYNAPSE framework may provide for acquiring data via an embedded, self-contained sensor module housed within a bit for acquiring at-bit measurements. As an example, such a module may be substantially nonmagnetic to reduce risk of interference with one or more sensors (e.g., consider one or more BHA sensors, etc.). As an example, a memory-mode logging scheme with optional preset sleep mode may provide for efficient data acquisition (e.g., rotational speed, shock and vibration, temperature, etc.). As shown in the example of FIG. 17, SYNAPSE framework results may be generated and/or utilized (see, e.g., various “synapse” labels in the example PI results).

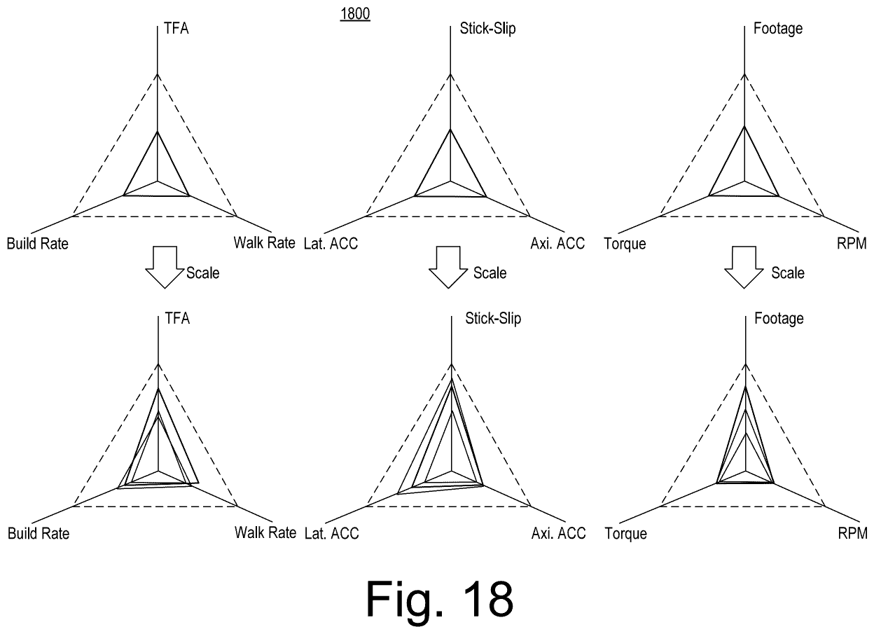

FIG. 18 shows an example of a GUI 1800 that may provide for rendering of graphics for visualization of PIs in one or more formats. For example, consider a normalized format and a scaled format. In such an example, the upper row may be a default format where the bottom row may be a scaled format that may be generated and rendered responsive to input (e.g., user interaction, automated assessment, etc.). As shown, the lower row of graphics in the GUI 1800 may provide for visualization of differences between three different pieces of equipment (e.g., bits, etc.) for performing one or more field operations. In the example of FIG. 18, the graphics are shown as spider plots where axes thereof correspond to PIs associated with stability. Hence, where stability performance of a bit is a concern, such a GUI may provide for facilitating decision-making as to bit selection from a number of candidate bits.

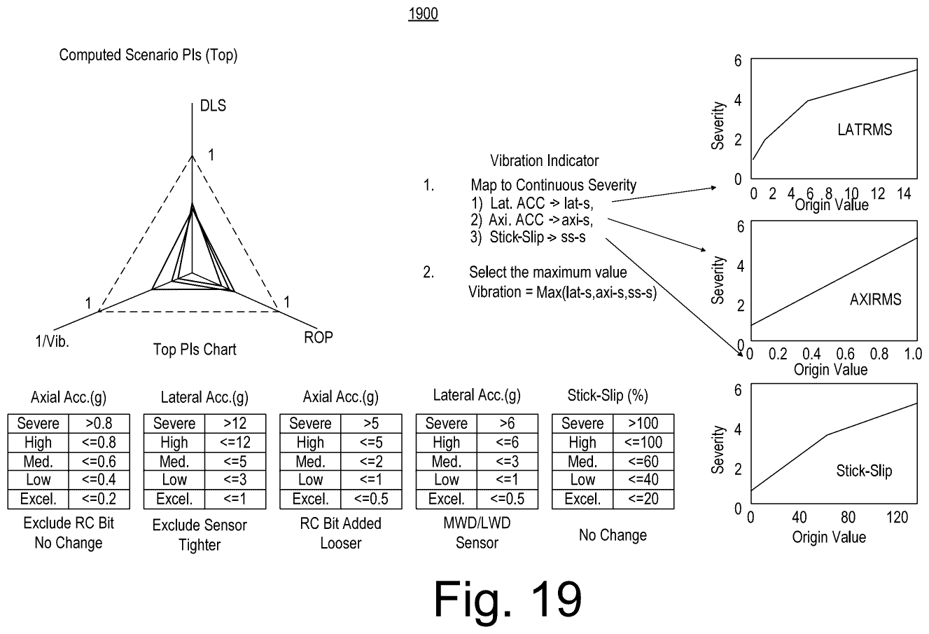

FIG. 19 shows an example of a GUI 1900 that includes various graphics, fields, tables, etc. As shown, the GUI 1900 may include a plot such as a spider plot of top PIs (e.g., a top PIs chart) for a number of pieces of equipment. For example, consider a number of candidate bits where PIs are plotted using a spider plot with axes for DLS, reciprocal vibration, and ROP. In the example of FIG. 19, the GUI 1900 includes various tables that may correspond to performance as to one or more drillstring modifications, which may aid in equipment selection. In the example of FIG. 19, the GUI 1900 includes various plots as to severity of vibration (e.g., shock and/or vibration) based on various PIs, which may include one or more of lateral acceleration, axial acceleration, and stick-slip related PIs.

As an example, one or more graphical user interface (GUI) toolkits may be utilized for generation of one or more GUIs. As an example, a GUI may be a widget or may include widgets. A widget may be utilized as a generic term to describe elements that make up a GUI (e.g., buttons, labels, windows, etc.). In the PySimpleGUI toolkit, widgets may be referred to as elements. For example, consider the Window( ) building block in the PySimpleGUI toolkit. In such an example, to create a Window( ), consider the following PYTHON language code (e.g., Py code):

# hello_world.py
import PySimpleGUI as sg
sg.Window(title=“Hello World”, layout=[[ ]], margins=(100, 50)).read( )

As an example, the Window( ) building block may take various different arguments, for example, in the foregoing example the Window( ) building block includes a title, a layout, and set the margins, which defines the size of the GUI window in pixels. As to the building block read( ), it returns one or more events that may be triggered in the Window( ) as a string as well as a values dictionary.

In various instances, a GUI may include graphics that may be rendered, for example, using vector graphics instructions. As to the aforementioned PySimpleGUI toolkit, it may be integrated with other features such as, for example, numpy and matplotlib. Below, an example of PYTHON language code includes import commands to import various features such that a plot may be rendered in a GUI:

import numpy as np
from matplotlib.backends.backend_tkagg import FigureCanvasTkAgg
import PySimpleGUI as sg
import matplotlib
fig = matplotlib.figure.Figure(figsize=(5, 4), dpi=100)
t = np.arange(0, 3, .01)
fig.add_subplot(111).plot(t, 2 * np.sin(2 * np.pi * t))

In the foregoing example, which tends to be relatively simply (e.g., a single plot in a GUI), various arguments (e.g., parameters) are specified. As to the example computational frameworks 121 of FIG. 1, GUIs may be more complex and include various parameters, some of which may be user configurable. For example, a GUI may include sub-GUIs that may be rendered from a menu, etc., to allow a user to configure colors, types of plots, units, layouts of elements, etc. As an example, a workflow may involve navigating through multiple GUIs where one or more of the multiple GUIs may be at least in part configurable by a user. In various instances, a user may customize (e.g., personalize) a GUI, for herself, for a team, for a company, etc. Customization may facilitate collaboration and/or otherwise sharing of information, results, actions, etc.

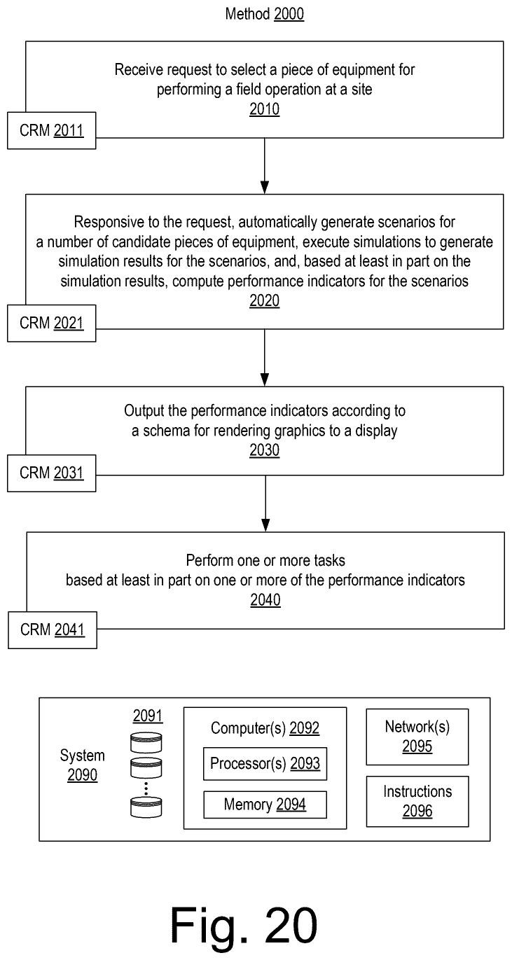

FIG. 20 shows an example of a method 2000 and an example of a system 2090. As shown, the method 2000 may include a reception block 2010 for receiving a request to select a piece of equipment for performing a field operation at a site; an automation block 2020 for, responsive to the request, automatically generating scenarios for a number of candidate pieces of equipment, executing simulations to generate simulation results for the scenarios, and, based at least in part on the simulation results, computing performance indicators for the scenarios; and an output block 2030 for outputting the performance indicators according to a schema for rendering graphics to a display. As shown, the method 2000 may include one or more other blocks such as, for example, a performance block 2040 for performing one or more tasks based at least in part on one or more of the performance indicators.

FIG. 20 also shows various computer-readable media (CRM) blocks 2011, 2021, 2031, and 2041. Such blocks may include instructions that are executable by one or more processors, which may be one or more processors of a computational framework, a system, a computer, etc. A computer-readable medium may be a computer-readable storage medium that is not a signal, not a carrier wave and that is non-transitory. For example, a computer-readable medium may be a physical memory component that may store information in a digital format.

In the example of FIG. 20, a system 2090 includes one or more information storage devices 2091, one or more computers 2092, one or more networks 2095 and instructions 2096. As to the one or more computers 2092, each computer may include one or more processors (e.g., or processing cores) 2093 and memory 2094 for storing the instructions 2096, for example, executable by at least one of the one or more processors. As an example, a computer may include one or more network interfaces (e.g., wired or wireless), one or more graphics cards, a display interface (e.g., wired or wireless), etc. The system 2090 may be specially configured to perform one or more portions of the method 2000 of FIG. 20.

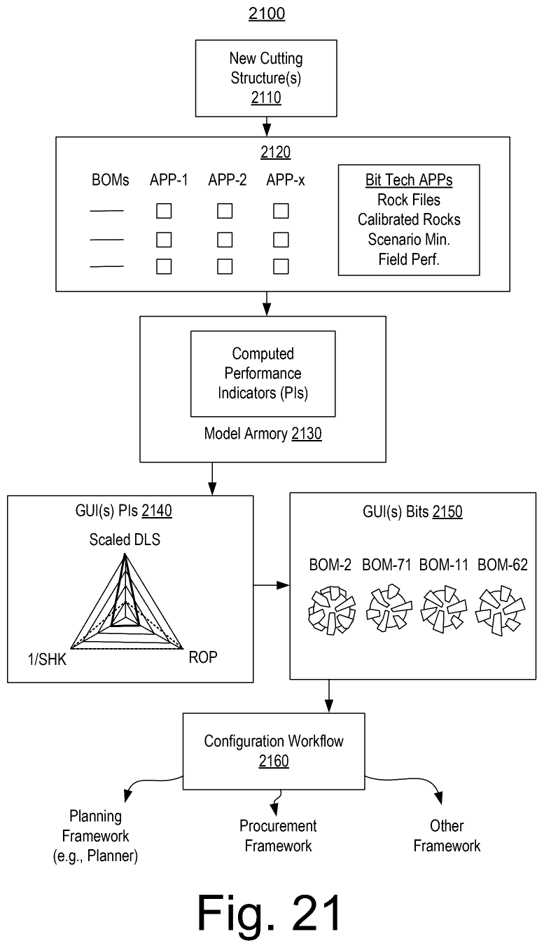

FIG. 21 shows an example of a workflow 2100 that includes a new cutting structure block 2110 for accessing one or more new cutting structures (e.g., one or more new bits, etc.), a scenario generation block 2120 for generating scenarios for the one or more new cutting structures (e.g., BOMs, etc.), which may be organized with respect to information as to rock files, calibrated rocks (e.g., formation models), scenario criteria (e.g., minimums, maximums, etc.), field performance, etc. As shown, a model armory block 2130 may provide for computing performance indicators (PIs) for the scenarios where, for example, the model armory 2130 may provide for accessing one or more simulators to perform one or more simulations, which may include one or more equipment and environment interaction simulations (e.g., consider drilling simulation, etc.). As shown, the workflow 2100 may include a rendering block 2140 for generating of one or more GUIs that may include graphics for performance indicators as to various cutting structures. In such an example, the workflow 2100 may include a rendering block 2150 for generating one or more GUIs that may include graphics for various cutting structures, which may be ordered, ranked, etc., based at least in part on one or more of the computed performance indicators. As an example, a cutting structure may be specified according to a BOM, which may be an identifier as may be utilized in a database (e.g., of a bit supplier, etc.). As shown, the workflow 2100 may include a configuration workflow block 2160 where one or more of the cutting structures and/or information associated therewith may be utilized to configure one or more subsequent workflows. For example, consider a planning workflow that may utilize a planning framework (e.g., a planner, etc.), a procurement workflow that may utilize a procurement framework (e.g., for ordering, procuring, etc., equipment), and/or one or more other workflows that may utilize one or more other frameworks. As an example, a framework may be a field operations framework such as, for example, the DRILLOPS framework that may provide for control of field operations (e.g., drilling, etc.).

As an example, a workflow may provide for selection of equipment using computed performance indicators for a number of scenarios. As an example, a framework may provide for pre-computing scenarios for computation of performance indicators where such performance indicators may be readily available for comparisons as to various candidate equipment (e.g., candidate drill bits, etc.).

As an example, various performance indicators may be based at least in part on simulation results where such simulation results may depend on one or more formation models, which may include one or more calibrated formation models. As an example, a framework may provide for calibration of a formation in a manner whereby computed performance indicators are compared to actual field data-based performance indicators. For example, an iterative workflow may aim to match simulation-based results to field data-based results by adjusting a formation model such that when a suitable match is achieved the formation model may be sufficiently adjusted to be considered to be a calibrated formation model that is calibrated to the field data (e.g., to a field site or field sites).

As an example, a computational framework may include a solver, which may be implemented via executable instructions. For example, consider a computational framework that includes a processor and memory accessible to the processor where executable instructions may be stored in the memory and accessed for execution by the processor to cause the computational framework to perform one or more actions. Such a computational framework may include one or more interfaces for receipt of information and/or for output of information, which may include values of parameters, an instruction, etc. As an example, a computational framework may be part of a controller. As an example, a computational framework may be part of a system.

As an example, various systems, methods, etc., may implement one or more ML models. As to types of ML models, consider one or more of a support vector machine (SVM) model, a k-nearest neighbors (KNN) model, an ensemble classifier model, a neural network (NN) model, etc. As an example, a machine learning model may be a deep learning model (e.g., deep Boltzmann machine, deep belief network, convolutional neural network, stacked auto-encoder, etc.), an ensemble model (e.g., random forest, gradient boosting machine, bootstrapped aggregation, AdaBoost, stacked generalization, gradient boosted regression tree, etc.), a neural network model (e.g., radial basis function network, perceptron, back-propagation, Hopfield network, etc.), a regularization model (e.g., ridge regression, least absolute shrinkage and selection operator, elastic net, least angle regression), a rule system model (e.g., cubist, one rule, zero rule, repeated incremental pruning to produce error reduction), a regression model (e.g., linear regression, ordinary least squares regression, stepwise regression, multivariate adaptive regression splines, locally estimated scatterplot smoothing, logistic regression, etc.), a Bayesian model (e.g., naïve Bayes, average on-dependence estimators, Bayesian belief network, Gaussian naïve Bayes, multinomial naïve Bayes, Bayesian network), a decision tree model (e.g., classification and regression tree, iterative dichotomiser 3, C4.5, C5.0, chi-squared automatic interaction detection, decision stump, conditional decision tree, M5), a dimensionality reduction model (e.g., principal component analysis, partial least squares regression, Sammon mapping, multidimensional scaling, projection pursuit, principal component regression, partial least squares discriminant analysis, mixture discriminant analysis, quadratic discriminant analysis, regularized discriminant analysis, flexible discriminant analysis, linear discriminant analysis, etc.), an instance model (e.g., k-nearest neighbor, learning vector quantization, self-organizing map, locally weighted learning, etc.), a clustering model (e.g., k-means, k-medians, expectation maximization, hierarchical clustering, etc.), etc.

As an example, a system may utilize one or more recurrent neural networks (RNNs). One type of RNN is referred to as long short-term memory (LSTM), which may be a unit or component (e.g., of one or more units) that may be in a layer or layers. A LSTM component may be a type of artificial neural network (ANN) designed to recognize patterns in sequences of data, such as time series data. When provided with time series data, LSTMs take time and sequence into account such that an LSTM may include a temporal dimension. For example, consider utilization of one or more RNNs for processing temporal data from one or more sources, optionally in combination with spatial data. Such an approach may recognize temporal patterns, which may be utilized for making predictions (e.g., as to a pattern or patterns for future times, etc.).

As an example, the TENSORFLOW framework (Google LLC, Mountain View, California) may be implemented, which is an open-source software library for dataflow programming that includes a symbolic math library, which may be implemented for machine learning applications that may include neural networks. As an example, the CAFFE framework may be implemented, which is a DL framework developed by Berkeley AI Research (BAIR) (University of California, Berkeley, California). As another example, consider the SCIKIT platform (e.g., scikit-learn), which utilizes the PYTHON programming language. As an example, a framework such as the APOLLO AI framework may be utilized (APOLLO.AI GmbH, Germany). As an example, a framework such as the PYTORCH framework (PyTorch Foundation) may be utilized.

As an example, a training method may include various actions that may operate on a dataset to train a ML model. As an example, a dataset may be split into training data and test data where test data may provide for evaluation. A method may include cross-validation of parameters and best parameters, which may be provided for model training.

The TENSORFLOW framework may run on multiple CPUs and GPUs (with optional CUDA (NVIDIA Corp., Santa Clara, California) and SYCL (The Khronos Group Inc., Beaverton, Oregon) extensions for general-purpose computing on graphics processing units (GPUs)). TENSORFLOW is available on 64-bit LINUX, MACOS (Apple Inc., Cupertino, California), WINDOWS (Microsoft Corp., Redmond, Washington), and mobile computing platforms including ANDROID (Google LLC, Mountain View, California) and IOS (Apple Inc.) operating system-based platforms.

TENSORFLOW computations may be expressed as stateful dataflow graphs; noting that the name TENSORFLOW derives from the operations that such neural networks perform on multidimensional data arrays. Such arrays may be referred to as “tensors”.

As an example, a method may include receiving a request to select a piece of equipment for performing a field operation at a site; responsive to the request, automatically generating scenarios for a number of candidate pieces of equipment, executing simulations to generate simulation results for the scenarios, and, based at least in part on the simulation results, computing performance indicators for the scenarios; and outputting the performance indicators according to a schema for rendering graphics to a display. In such an example, the piece of equipment may be or include a drillstring component. For example, consider a drillstring component that is or includes a drill bit.

As an example, simulations may include one or more drilling simulations performed by one or more different drilling simulators.

As an example, a site may be a wellsite characterized at least in part by a formation model. In such an example, a method may include performing simulations that include at least one simulation that depends on the formation model and/or include performing one or more simulations that include at least one simulation that simulates equipment and formation interactions.

As an example, a method may include performing simulations that include at least one static simulation and at least one dynamic simulation.

As an example, a method may include generating scenarios (e.g., automatically) at least in part by accessing one or more equipment databases that include equipment specifications.

As an example, a method may include generating scenarios (e.g., automatically) at least in part using a first computing system where, in such a method, executing simulations to generate simulation results may include using a second computing system. In such an example, the first computing system may be a local computing system and the second computing system may be a remote, cloud-based computing system. As an example, a request may be received by a local computing system.

As an example, performance indicators may include a hierarchy of performance indicators. For example, consider a hierarchy of performance indicators that includes classes and sub-classes of performance indicators.

As an example, a method may include generating scenarios at least in part by organizing scenarios according to a schema. In such an example, the method may include outputting performance indicators according to the schema in a manner that includes appending a data structure organized according to the schema.

As an example, a schema may be or include a JSON-based schema.

As an example, a method may include selecting one of a number of pieces of equipment based at least in part on a number of performance indicators. In such an example, such piece or pieces of equipment may be assembled on a drillstring or other tool string and utilized in a subsurface environment. For example, consider selecting a drill bit and coupling the drill bit to a drillstring as an assembly of components and running the drillstring into a borehole to perform drilling operations that may lengthen the borehole. In such an approach, drilling may be improved and/or a borehole as a physical product of drilling may be improved (e.g., consider a borehole with improved borewall integrity due to less shock and vibration, etc., during drilling of the borehole due in part to selection of a drill bit, etc.).

As an example, a system may include one or more processors; memory accessible to at least one of the one or more processors; and processor-executable instructions stored in the memory and executable to instruct the system to: receive a request to select a piece of equipment for performing a field operation at a site; responsive to the request, automatically generate scenarios for a number of candidate pieces of equipment, execute simulations to generate simulation results for the scenarios, and, based at least in part on the simulation results, compute performance indicators for the scenarios; and output the performance indicators according to a schema for rendering graphics to a display.

As an example, one or more computer-readable storage media may include processor-executable instructions to instruct a computing system to: receive a request to select a piece of equipment for performing a field operation at a site; responsive to the request, automatically generate scenarios for a number of candidate pieces of equipment, execute simulations to generate simulation results for the scenarios, and, based at least in part on the simulation results, compute performance indicators for the scenarios; and output the performance indicators according to a schema for rendering graphics to a display.

As an example, a computer program product that may include computer-executable instructions to instruct a computing system to perform one or more methods such as one or more of the methods described herein (e.g., in part, in whole and/or in various combinations).

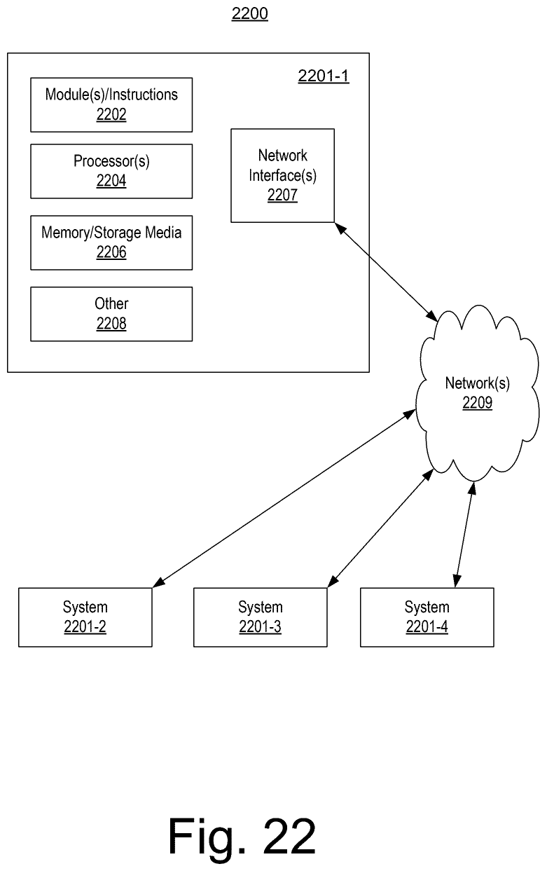

In some embodiments, a method or methods may be executed by a computing system. FIG. 22 shows an example of a system 2200 that may include one or more computing systems 2201-1, 2201-2, 2201-3 and 2201-4, which may be operatively coupled via one or more networks 2209, which may include wired and/or wireless networks. As shown, the system 2200 may include one or more other components 2208.

As an example, a system may include an individual computer system or an arrangement of distributed computer systems. In the example of FIG. 22, the computer system 2201-1 may include one or more modules 2202, which may be or include processor-executable instructions, for example, executable to perform various tasks (e.g., receiving information, requesting information, processing information, simulation, outputting information, etc.).

As an example, a module may be executed independently, or in coordination with, one or more processors 2204, which is (or are) operatively coupled to one or more storage media 2206 (e.g., via wire, wirelessly, etc.). As an example, one or more of the one or more processors 2204 may be operatively coupled to at least one of one or more network interface 2207. In such an example, the computer system 2201-1 may transmit and/or receive information, for example, via the one or more networks 2209 (e.g., consider one or more of the Internet, a private network, a cellular network, a satellite network, etc.). As shown, one or more other components 2208 may be included in the computer system 2201-1.

As an example, the computer system 2201-1 may receive from and/or transmit information to one or more other devices, which may be or include, for example, one or more of the computer systems 2201-2, etc. A device may be located in a physical location that differs from that of the computer system 2201-1. As an example, a location may be, for example, a processing facility location, a data center location (e.g., server farm, etc.), a rig location, a wellsite location, a downhole location, etc.

As an example, a processor may be or include a microprocessor, microcontroller, processor module or subsystem, programmable integrated circuit, programmable gate array, or another control or computing device.

As an example, the storage media 2206 may be implemented as one or more computer-readable or machine-readable storage media. As an example, storage may be distributed within and/or across multiple internal and/or external enclosures of a computing system and/or additional computing systems.

As an example, a storage medium or storage media may include one or more different forms of memory including semiconductor memory devices such as dynamic or static random access memories (DRAMs or SRAMs), erasable and programmable read-only memories (EPROMs), electrically erasable and programmable read-only memories (EEPROMs) and flash memories, magnetic disks such as fixed, floppy and removable disks, other magnetic media including tape, optical media such as compact disks (CDs) or digital video disks (DVDs), BLUERAY disks, or other types of optical storage, or other types of storage devices.

As an example, a storage medium or media may be located in a machine running machine-readable instructions, or located at a remote site from which machine-readable instructions may be downloaded over a network for execution.

As an example, various components of a system such as, for example, a computer system, may be implemented in hardware, software, or a combination of both hardware and software (e.g., including firmware), including one or more signal processing and/or application specific integrated circuits.

As an example, a system may include a processing apparatus that may be or include a general-purpose processors or application specific chips (e.g., or chipsets), such as ASICs, FPGAs, PLDs, or other appropriate devices.

As an example, a device may be a mobile device that includes one or more network interfaces for communication of information. For example, a mobile device may include a wireless network interface (e.g., operable via IEEE 802.11, ETSI GSM, BLUETOOTH, satellite, etc.). As an example, a mobile device may include components such as a main processor, memory, a display, display graphics circuitry (e.g., optionally including touch and gesture circuitry), a SIM slot, audio/video circuitry, motion processing circuitry (e.g., accelerometer, gyroscope), wireless LAN circuitry, smart card circuitry, transmitter circuitry, GPS circuitry, and a battery. As an example, a mobile device may be configured as a cell phone, a tablet, etc. As an example, a method may be implemented (e.g., wholly or in part) using a mobile device. As an example, a system may include one or more mobile devices.

As an example, a system may be a distributed environment, for example, a so-called “cloud” environment where various devices, components, etc. interact for purposes of data storage, communications, computing, etc. As an example, a device or a system may include one or more components for communication of information via one or more of the Internet (e.g., where communication occurs via one or more Internet protocols), a cellular network, a satellite network, etc. As an example, a method may be implemented in a distributed environment (e.g., wholly or in part as a cloud-based service).

As an example, information may be input from a display (e.g., consider a touchscreen), output to a display or both. As an example, information may be output to a projector, a laser device, a printer, etc. such that the information may be viewed. As an example, information may be output stereographically or holographically. As to a printer, consider a 2D or a 3D printer. As an example, a 3D printer may include one or more substances that may be output to construct a 3D object. For example, data may be provided to a 3D printer to construct a 3D representation of a subterranean formation. As an example, layers may be constructed in 3D (e.g., horizons, etc.), geobodies constructed in 3D, etc. As an example, holes, fractures, etc., may be constructed in 3D (e.g., as positive structures, as negative structures, etc.).

Although only a few examples have been described in detail above, those skilled in the art will readily appreciate that many modifications are possible in the examples. Accordingly, all such modifications are intended to be included within the scope of this disclosure as defined in the following claims. In the claims, means-plus-function clauses are intended to cover the structures described herein as performing the recited function and not only structural equivalents, but also equivalent structures. Thus, although a nail and a screw may not be structural equivalents in that a nail employs a cylindrical surface to secure wooden parts together, whereas a screw employs a helical surface, in the environment of fastening wooden parts, a nail and a screw may be equivalent structures.

What is claimed is:

1. A method comprising:
receiving a request to select a piece of equipment for performing a field operation at a site;
responsive to the request, automatically generating scenarios for a number of candidate pieces of equipment, executing simulations to generate simulation results for the scenarios, and, based at least in part on the simulation results, computing performance indicators for the scenarios; and
outputting the performance indicators according to a schema for rendering graphics to a display.

2. The method of claim 1, wherein the piece of equipment comprises a drillstring component.

3. The method of claim 2, wherein the drillstring component comprises a drill bit.

4. The method of claim 2, wherein the simulations comprise drilling simulations performed by one or more different drilling simulators.

5. The method of claim 1, wherein the site comprises a wellsite characterized at least in part by a formation model.

6. The method of claim 5, wherein the simulations comprise at least one simulation that depends on the formation model.

7. The method of claim 5, wherein the simulations comprise at least one simulation that simulates equipment and formation interactions.

8. The method of claim 1, wherein the simulations comprise at least one static simulation and at least one dynamic simulation.

9. The method of claim 1, wherein the generating comprises accessing one or more equipment databases that comprise equipment specifications.

10. The method of claim 1, wherein the generating comprises using a first computing system and wherein the executing comprises using a second computing system.

11. The method of claim 10, wherein the first computing system comprises a local computing system and wherein the second computing system comprises a remote, cloud-based computing system.

12. The method of claim 11, wherein the request is received by the local computing system.

13. The method of claim 1, wherein the performance indicators comprise a hierarchy of performance indicators.

14. The method of claim 13, wherein the hierarchy of performance indicators comprises classes and sub-classes of performance indicators.

15. The method of claim 1, wherein the generating the scenarios comprises organizing the scenarios according to the schema.

16. The method of claim 15, wherein the outputting the performance indicators according to the schema comprises appending a data structure organized according to the schema.

17. The method of claim 1, wherein the schema comprises a JSON-based schema.

18. The method of claim 1, comprising selecting one of the pieces of equipment based at least in part on the performance indicators.

19. A system comprising:
one or more processors;
memory accessible to at least one of the one or more processors; and
processor-executable instructions stored in the memory and executable to instruct the system to:
receive a request to select a piece of equipment for performing a field operation at a site;
responsive to the request, automatically generate scenarios for a number of candidate pieces of equipment, execute simulations to generate simulation results for the scenarios, and, based at least in part on the simulation results, compute performance indicators for the scenarios; and
output the performance indicators according to a schema for rendering graphics to a display.

20. One or more computer-readable storage media comprising processor-executable instructions to instruct a computing system to:
receive a request to select a piece of equipment for performing a field operation at a site;
responsive to the request, automatically generate scenarios for a number of candidate pieces of equipment, execute simulations to generate simulation results for the scenarios, and, based at least in part on the simulation results, compute performance indicators for the scenarios; and
output the performance indicators according to a schema for rendering graphics to a display.
